(19) United States
(12) Patent Application Publication
(10) Pub. No.: US 2017/0040379 A1
(43) Pub. Date: Feb. 9, 2017

(54) SEMICONDUCTOR MEMORY DEVICE AND METHOD FOR MANUFACTURING SAME

(71) Applicant: HITACHI, LTD.

(72) Inventors: Yoshitaka SASAGO, Tokyo (JP); Hiroshi YOSHITAKE, Tokyo (JP); Koji FUJISAKI, Tokyo (JP); Takashi KOBAYASHI, Tokyo (JP); Makoto KUDO, Tokyo (JP)

(21) Appl. No.: 15/106,133

(22) PCT Filed: Dec. 27, 2013
(86) PCT No.: PCT/JP2013/085222

§ 371 Date: Jun. 17, 2016

(51) Int. Cl. H01L 27/24; H01L 23/528

(52) U.S. Cl. CPC H01L 27/249; H01L 23/528; H01L 27/2454; H01L 45/06

(57) ABSTRACT

An object of the present invention is to reduce a pitch of selection transistors to select two directions in a semiconductor substrate surface of a three-dimensional vertical semiconductor storage device to reduce a dimension in the semiconductor substrate surface.

Gates of selection transistors extending in the same direction are formed by a different process for every other gate, so that the thickness of channel semiconductor layers of the selection transistors can be reduced to almost the same thickness of the thickness of an inversion layer while the channel semiconductor layers and an electrode are contacted over a wide area. On/off control can be executed independently on the channel semiconductor layers formed at two sidewalls of the gates of the selection transistors formed at a pitch of 2F. As a result, dimensions of two directions in the semiconductor substrate surface can be set to 2F without generating double selection.

### TECHNICAL FIELD

The present invention relates to a selection transistor that reduces a dimension in a semiconductor substrate surface of a three-dimensional vertical semiconductor storage device and selects two directions in the semiconductor substrate surface.

### BACKGROUND ART

Recently, a phase change memory using chalcogenide materials as recording materials is studied actively. The phase change memory is a type of resistance change type memory that stores information using a characteristic that recording materials between electrodes have different resistance states.

The phase change memory stores information using a characteristic that a resistance value of a phase change material such as Ge₂Sb₂Te₅ is different in an amorphous state and a crystalline state. In the amorphous state, resistance is high and in the crystalline state, the resistance is low. Therefore, information read from a memory cell is executed by applying a potential difference to both ends of an element, measuring a current flowing through the element, and determining a high resistance state/low resistance state of the element.

In the phase change memory, data is rewritten by changing electrical resistance of a phase change film to a different state by a Joule heat generated by the current. A reset operation, that is, an operation for changing a state to the amorphous state of the high resistance is executed by causing a large current to flow for a short time, melting a phase change material, and decreasing the current rapidly for rapid cooling. Meanwhile, a set operation, that is, an operation for changing a state to the crystalline state of the low resistance is executed by causing a current sufficient for maintaining the phase change material at a crystallization temperature to flow for a long time. In the phase change memory, if miniaturization advances, a current necessary for changing a state of the phase change film decreases. For this reason, the phase change memory is miniaturized in principle. Therefore, a study is performed actively.

In PTL 1, a configuration in which a plurality of through-holes penetrating entire layers are formed by collective processing in a lamination structure where a plurality of gate electrode materials and a plurality of Insulating films are alternately laminated and a gate insulating film, a channel layer, and a phase change film are formed in the through-holes and are processed is disclosed as a method of highly integrating a phase change memory. Each memory cell includes a cell transistor and a phase change element that are connected in parallel and a plurality of memory cells are connected in series in a longitudinal direction, that is, a normal direction to a semiconductor substrate and form phase change memory chains. In an array configuration of PTL 1, each phase change memory chain is selected by a vertical selection transistor. A channel semiconductor layer of each selection transistor has a structure in which the channel semiconductor layer is separated for every phase change memory chain. In the vertical selection transistor of PTL 1, because holes provided with channels are formed in gates processed into strips, it is necessary to increase widths of the gates as compared with a minimum processing dimension. A pitch of the gates becomes about 3F when the minimum processing dimension is set as F and a pitch of the memory cells also becomes 3F. In addition, technology for applying the same vertical structure to a flash memory is disclosed in PTL 2.

As technology for reducing the pitch of the gates to 2F, a method of PTL 3 is disclosed. However, because it is necessary to form the selection transistor in two steps to perform selection of one direction in the semiconductor substrate surface, an integration degree is improved, but the number of processes increases.

In addition, technology for reducing the pitch of the gates to 2F by the selection transistor of one step is disclosed in PTL 4. A so-called gate last process for processing a semiconductor layer becoming a channel and forming a gate insulating film and a gate in a space portion in a space portion of the processed channel semiconductor layer is used.

### CITATION LIST

### Patent Literature

PTL 1: Japanese Patent Application Laid-Open No. 2008-160004

PTL 2: Japanese Patent Application Laid-Open No. 2007-266143

PTL 3: Japanese Patent Application Laid-Open No. 2009-4517

PTL 4: Japanese Patent Application Laid-Open No. 2013-120618

### SUMMARY OF INVENTION

### Technical Problem

Because the vertical selection transistor described in PTL 4 can be formed in one step, the number of processes is small and the pitch of the gates can be reduced to 2F. However, there are the following problems. That is, in a structure in which channel semiconductor layers are formed on both sidewalls of the gate with the gate insulating film therebetween, if an on voltage is applied to one gate, inversion layers are formed on surfaces of the gate side of the channel semiconductor layers of both sides to which an on voltage has been applied. For this reason, the two channel semiconductor layers are turned on at the same time. If this transistor is used as the selection transistor of the semiconductor storage device, memory cells connected to two channels that are turned on at the same time cannot be operated independently. To enable any one of the two channels to be selected, the thickness of the channel semiconductor layer needs to be set small to become almost equal to the thickness of the inversion layer, for example, about 5 nm and an off voltage needs to be applied to the gate of the opposite side contacting the channel semiconductor layer to be turned off with the gate insulating film therebetween.

However, when the channel semiconductor layer having the thickness of about 5 nm is formed, processing of 5 nm cannot be performed with high precision, even if a gate first process is used or the gate last process is used. For this reason, it becomes essential to use high expensive lithography technology such as extreme ultraviolet (EUV) lithography, which results in increasing a manufacturing cost of the semiconductor storage device. Because the channel semiconductor layer processed with a dimension of 5 nm contacts the upper and lower electrode with a width of 5 nm, contact resistance of the electrodes and the channel semiconductor layer is increased and an on current of the transistor is decreased.

The present invention has been made in view of the above problems. That is, an object of the present invention is to provide a vertical selection transistor having a large on current and having a gate pitch of 2F, with a simple process. As a result, an integration degree of memory cells can be improved and a large capacity and a low cost are enabled.

### Solution to Problem

In order to resolve the above problems, in the present invention, a semiconductor storage device includes: a plate-like lower electrode which is formed on a semiconductor substrate; an upper electrode which is formed on the lower electrode; a plurality of memory chains which are disposed between the lower electrode and the upper electrode and are obtained by connecting a plurality of memory cells to be electrically rewritable in series; and a first selection transistor which is connected to one end of the memory chains, wherein the plurality of memory chains are arranged in a matrix along a first direction in a semiconductor substrate surface and a second direction orthogonal to the first direction in the semiconductor substrate surface, with a longitudinal direction thereof matched with a normal direction of the semiconductor substrate, the first selection transistor has a plurality of gates which are formed to be arranged in parallel in the first direction at the same pitch as an arrangement pitch of the memory chains of the first direction and extend in the second direction, a gate insulating film which is formed to contact each facing sidewall between the plurality of gates, and a first channel semiconductor layer which is formed to be interposed by the plurality of gates with the gate insulating film therebetween, and in the first channel semiconductor layer, both channel semiconductor layers formed with the gate insulating film therebetween in the vicinity of both sides of every other gate among the plurality of gates are connected between the gate and the lower electrode or the upper electrode as a result of a simultaneous film formation process or a part of both channel semiconductor layers remains between the gate and the lower electrode or the upper electrode as the result of the simultaneous film formation process.

In addition, to resolve the above problems, in the present invention, the memory cell is a phase change memory and the semiconductor storage device further includes a second selection transistor which is connected in series to the first selection transistor between the lower electrode and the memory chain array, in addition to the first selection transistor. The second selection transistor has a plurality of gates which are formed to be arranged in parallel in the second direction at the same pitch as an arrangement pitch of the memory chains of the second direction and extend in the first direction, a gate insulating film which is formed to contact each facing sidewall between the plurality of gates, and a second channel semiconductor layer which is formed to be interposed by the plurality of gates with the gate insulating film therebetween. The second channel semiconductor layer of the second selection transistor faces the gate of the second selection transistor with the gate insulating film therebetween at both sides of the second direction, the gate of the second selection transistor faces the second channel semiconductor layer with the gate insulating film therebetween at both sides of the second direction, and the gate of the second selection transistor has a shape different for every other gate in the second direction.

In addition, to resolve the above problems, in the present invention, a method of manufacturing a semiconductor storage device includes: (a) a step of forming a metal film becoming a lower electrode on a semiconductor substrate with an interlayer insulating film therebetween; (b) a step of forming a first insulating film on the lower electrode; (c) a step of forming a first gate electrode layer and a second insulating film on the first insulating film; (d) a step of patterning the second insulating film, the first gate electrode layer, and the first insulating film to be arranged with a predetermined width at a double pitch of an arrangement pitch of a memory chain array of a second direction in a semiconductor substrate surface and extend in a first direction in the semiconductor substrate surface; (e) a step of forming a first gate insulating film not to completely bury a space formed by the step (d); (f) a step of removing a top surface of a pattern formed by the step (e) and the first gate insulating film of a space portion on the lower electrode; (g) a step of forming a first channel semiconductor not to completely bury a space formed by the step (f); (h) a step of forming a second gate insulating film not to completely bury a space formed by the step (g); (i) a step of forming a second gate electrode layer; and (j) a step of separating the second gate electrode layer formed by the step (i) by etch-back processing for each groove formed by the step (d).

### Advantageous Effects of Invention

According to a semiconductor storage device according to the present invention, a suitable memory cell array can be manufactured by increasing a density and a large capacity and a low cost of the semiconductor storage device can be realized. In addition, the semiconductor storage device having the large capacity and the low cost is applied to an information processing device such as storages and servers, so that the information processing device can improve performance using a storage device having a low cost and a large capacity.

### BRIEF DESCRIPTION OF DRAWINGS

FIG. 1 is an entire plan view of a semiconductor storage device according to the present invention.

FIG. 2 is a partial three-dimensional schematic diagram of a semiconductor storage device according to a first embodiment of the present invention.

FIG. 3 is a three-dimensional schematic diagram of a memory cell array according to the first embodiment of the present invention.

FIGS. 4(a) to 4(c) are diagrams illustrating a reset operation, a set operation, and a read operation of the memory cell array according to the first embodiment of the present invention.

FIG. 5 is a diagram illustrating the read operation of the memory cell array according to the first embodiment of the present invention.

FIG. 6 is a diagram illustrating the set operation of the memory cell array according to the first embodiment of the present invention.

FIG. 7 is a diagram illustrating the reset operation of the memory cell array according to the first embodiment of the present invention.

FIGS. 8(a) and 8(b) are cross-sectional views illustrating a method of manufacturing the semiconductor storage device according to the first embodiment of the present invention.

FIGS. 9(a) and 9(b) are cross-sectional views illustrating a method of manufacturing the semiconductor storage device according to the first embodiment of the present invention.

FIGS. 10(a) and 10(b) are cross-sectional views illustrating a method of manufacturing the semiconductor storage device according to the first embodiment of the present invention.

FIGS. 11(a) and 11(b) are cross-sectional views illustrating a method of manufacturing the semiconductor storage device according to the first embodiment of the present invention.

FIGS. 12(a) and 12(b) are cross-sectional views illustrating a method of manufacturing the semiconductor storage device according to the first embodiment of the present invention.

FIGS. 13(a) and 13(b) are cross-sectional views illustrating a method of manufacturing the semiconductor storage device according to the first embodiment of the present invention.

FIGS. 14(a) and 14(b) are cross-sectional views illustrating a method of manufacturing the semiconductor storage device according to the first embodiment of the present invention.

FIGS. 15(a) and 15(b) are cross-sectional views illustrating a method of manufacturing the semiconductor storage device according to the first embodiment of the present invention.

FIGS. 16(a) and 16(b) are cross-sectional views illustrating a method of manufacturing the semiconductor storage device according to the first embodiment of the present invention.

FIGS. 17(a) and 17(b) are cross-sectional views illustrating a method of manufacturing the semiconductor storage device according to the first embodiment of the present invention.

FIGS. 18(a) and 18(b) are cross-sectional views illustrating a method of manufacturing the semiconductor storage device according to the first embodiment of the present invention.

FIGS. 19(a) and 19(b) are cross-sectional views illustrating a method of manufacturing the semiconductor storage device according to the first embodiment of the present invention.

FIG. 20 is a cross-sectional view illustrating a method of manufacturing the semiconductor storage device according to the first embodiment of the present invention.

FIG. 21 is a cross-sectional view illustrating a method of manufacturing the semiconductor storage device according to the first embodiment of the present invention.

FIG. 22 is a cross-sectional view illustrating a method of manufacturing the semiconductor storage device according to the first embodiment of the present invention.

FIG. 23 is a three-dimensional schematic diagram of a memory cell array of a semiconductor storage device according to a second embodiment of the present invention.

FIG. 24 is a cross-sectional view of the semiconductor storage device according to the second embodiment of the present invention.

FIG. 25 is an equivalent circuit diagram of the semiconductor storage device according to the second embodiment of the present invention and illustrates a voltage condition of a read operation.

FIG. 26 is a three-dimensional schematic diagram of a memory cell array of a semiconductor storage device according to a third embodiment of the present invention.

FIG. 27(a) is a cross-sectional view of the semiconductor storage device according to the third embodiment of the present invention and FIG. 27(b) is a cross-sectional view of a memory cell.

FIG. 28 is an equivalent circuit diagram of the semiconductor storage device according to the third embodiment of the present invention.

FIG. 29 is a cross-sectional view illustrating a method of manufacturing a semiconductor storage device according to a fourth embodiment of the present invention.

FIG. 30 is a cross-sectional view illustrating a method of manufacturing the semiconductor storage device according to the fourth embodiment of the present invention.

FIG. 31 is a cross-sectional view illustrating a method of manufacturing the semiconductor storage device according to the fourth embodiment of the present invention.

### DESCRIPTION OF EMBODIMENTS

Hereinafter, embodiments of the present invention will be described in detail on the basis of the drawings. Throughout all diagrams to describe the embodiments, members having the same functions are denoted with the same reference numerals and repetitive description thereof is omitted. In addition, it is previously said that places describing characteristic configurations are not limited to the individual embodiments and the same effect is obtained when a common configuration is taken.

### First Embodiment

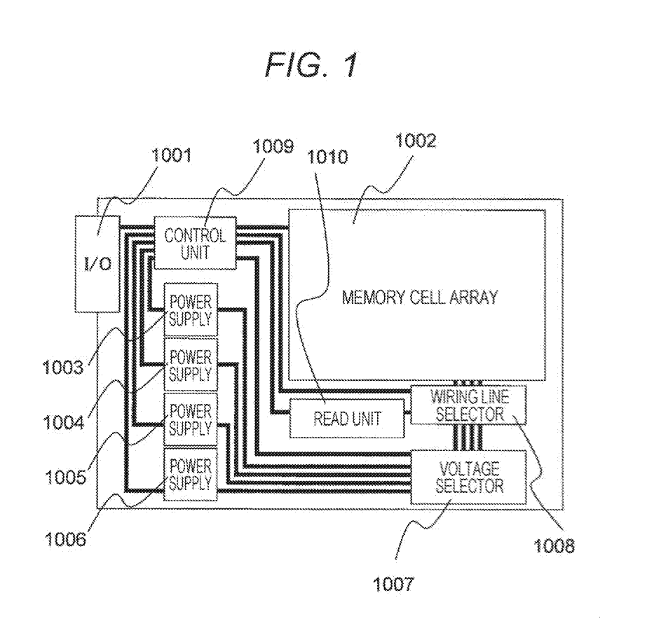

FIG. 1 is an entire view illustrating a semiconductor storage device using a phase change memory to be a first embodiment of the present invention. As illustrated in FIG. 1, the semiconductor storage device according to the first embodiment of the present invention includes an I/O interface 1001 including an input/output buffer to exchange data with the outside, a memory cell array 1002, a plurality of voltage sources 1003 to 1006 to supply a plurality of different voltages, a voltage selector 1007 to select voltages from the voltage sources 1003 to 1006, a wiring line selector 1008 to select a connection destination of an output from the voltage selector 1007 from wiring lines such as bit lines and word lines of the memory cell array 1002, and a control unit 1009 to wholly control the device. A read unit 1010 having a sense amplifier is included in the wiring line selector 1008.

When data is input from an external device to the I/O interface 1001, the control unit 1009 selects a voltage for data write by the voltage selector 1007, generates voltage pulses by the power supplies 1003 to 1006, and supplies the voltage pulses to a predetermined wiring line of the memory cell array 1002 by the wiring line selector 1008. As a result, data input to a phase change memory cell of the memory cell array is written.

If a data read signal is input from the external device to the I/O interface 1001, the control unit 1009 selects a voltage for data read by the voltage selector 1007, generates voltage pulses by the power supplies 1003 to 1006, and supplies the voltage pulses to a predetermined wiring line of the memory cell array 1002 by the wiring line selector 1008. As a supply result of the voltage pulses, a read current is read by the read unit 1010, this becomes reproduction of stored data, and read data is supplied to the external device via the control unit 1009 and the I/O interface 1001.

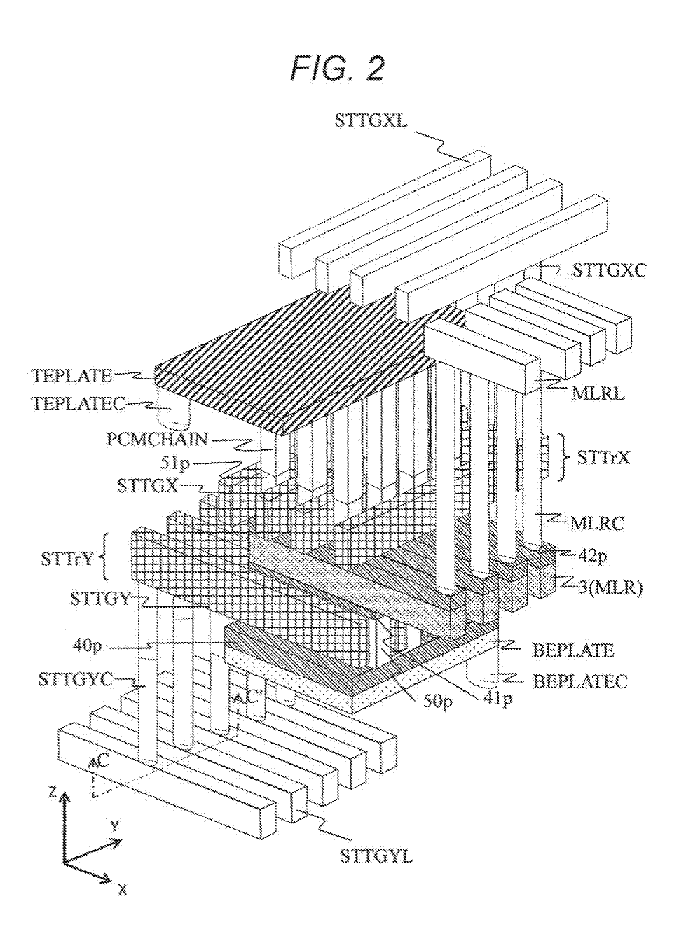

FIG. 2 is a three-dimensional schematic diagram illustrating a configuration of a memory cell array unit of the semiconductor storage device according to the first embodiment of the present invention. Plate-like electrodes TEPLATE and BEPLATE, electrodes 3 (MLR) extending in an X direction, phase change memory chains (cells) PCMCHAIN, X selection transistors STTrX extending in a Y direction and realizing selection of PCMCHAIN of the X direction, and Y selection transistors STTrY extending in the X direction and realizing selection of PCMCHAIN of the Y direction in a set operation and a reset operation are illustrated. In addition, gates of STTrX and STTrY are STTGX and STTGY, respectively. In FIG. 2, TEPLATEC to connect TEPLATE and a circuit on a semiconductor substrate, BEPLATEC to connect BEPLATE and the circuit on the semiconductor substrate, contacts STTGXC reaching STTGX, wiring lines STTGXL to feed STTGX via STTGXC, contacts STTGYC reaching STTGY, and wiring lines STTGYL to feed STTGY via STTGYC are further illustrated.

Although not illustrated in FIG. 2, STTGYL is connected to the circuit on the semiconductor substrate and STTYC and STTGXL is connected to the circuit on the semiconductor substrate and STTGXC, so that appropriate positions can be fed. If attention is paid to elevations of STTGXL and STTGYL, STTGYC is formed from a lower side with respect to STTGY extending in parallel below the wiring line MLR for the read operation and is connected to STTGYL. Meanwhile, the contact STTGXC is formed from an upper side with respect to STTGX formed to be orthogonal to MLR on MLR and is connected to STTGXL. The contact for the gate is easily formed from the upper side. However, MLR is formed at a narrow pitch. For this reason, if the contact is formed from the upper side for STTGY, it is necessary to separate MLR. If the contact for STTGY is formed from the lower side, it is not necessary to separate MLR at a formation portion of STTGYC. MLR is connected to MLRL via MLRC and MLRL is connected to the read unit 1010.

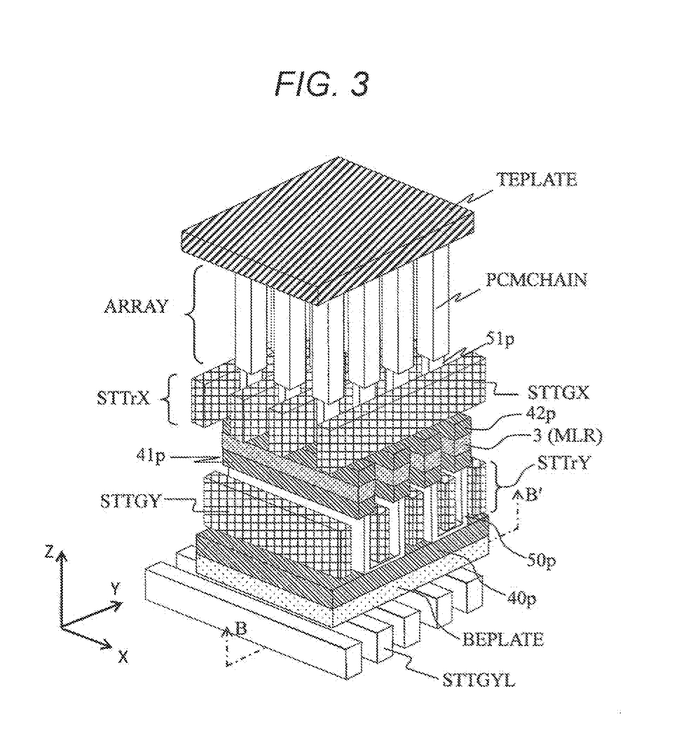

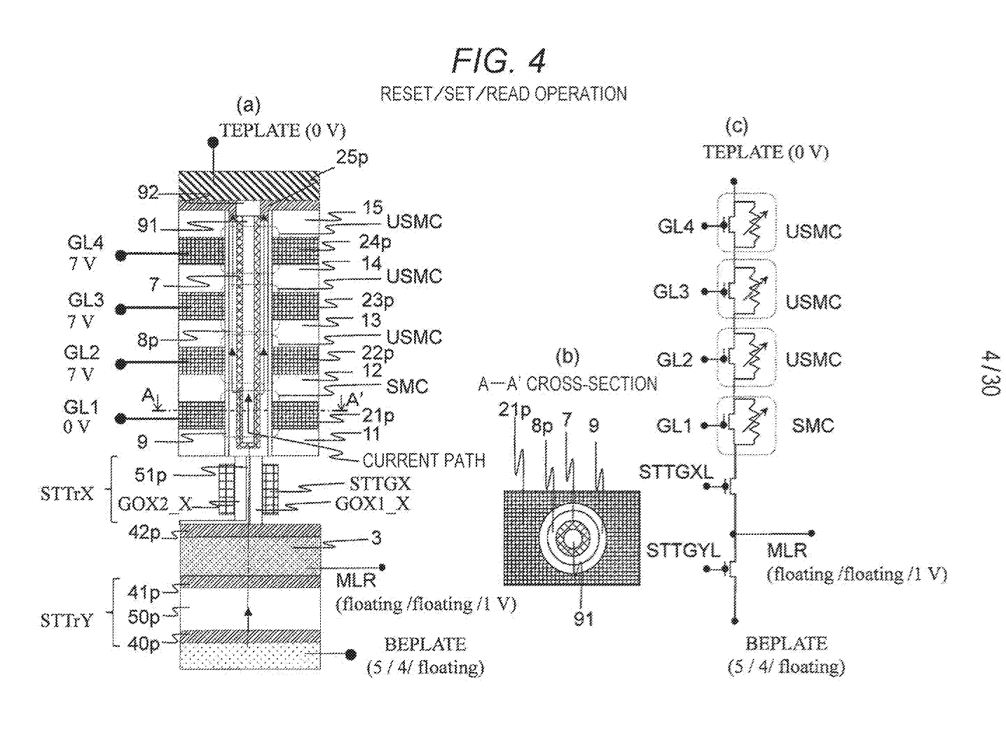

FIG. 3 illustrates an extraction result of an array of a matrix shape of PCMCHAIN and portions on and below the array, in FIG. 2. The wiring lines STTGYL are also illustrated in a lower portion. The electrode 3 (MLR) extends in the X direction and functions as the wiring line MLR to select the phase change memory PCMCHAIN in the Y direction in the read operation. The X selection transistor STTrX to select PCMCHAIN in the X direction is formed on the electrode 3 (MLR). The gate STTGX of STTrX extends in the Y direction orthogonal to the electrode 3 and a channel semiconductor layer 51p is formed in a space between the gates with a gate insulating film therebetween. As illustrated in FIG. 4 (a), the channel semiconductor layer 51p is connected to the electrode 3 via an N-type semiconductor layer 42p. A portion on the channel semiconductor layer 51p is connected to a channel semiconductor layer 8p forming PCMCHAIN. The channel semiconductor layer 51p is separated in the X direction and the Y direction for every PCMCHAIN. The phase change memory chain PCMCHAIN is formed on the X selection transistor STTrX. A diffusion layer including an N-type semiconductor layer 25p is formed on the channel semiconductor layer 8p and is connected to the plate-like electrode TEPLATE becoming an upper electrode. Although not illustrated in FIG. 3 to facilitate viewing, PCMCHAIN is formed in a hole of a Z direction formed in a laminate in which gate polysilicon layers 21p, 22p, 23p, and 24p becoming cell gate electrodes and insulating films 11, 12, 13, 14, and 15 are alternately laminated. A surrounding detailed structure of PCMCHAIN is described in FIGS. 4(a) to 4 (c).

The Y selection transistor STTrY that extends in the same X direction as the electrode 3 and selects PCMCHAIN in the Y direction when the set operation and the reset operation to be described below are executed is formed below the electrode 3. The gate STTGY of STTrY extends in the X direction parallel to the electrode 3 and the channel semiconductor layer 50p is formed in a space between the gates with a gate insulating film therebetween. A portion on the channel semiconductor layer 50p is connected to the electrode 3 via the N-type semiconductor layer 41p. A portion below the channel semiconductor layer 50p is connected to the plate-like electrode BEPLATE via the N-type semiconductor layer 40p. Because source/drain diffusion layers of the channel semiconductor layer 50p are the N-type semiconductor layers 40p and 41p, a length of the channel semiconductor layer 50p extending in the X direction becomes a channel width of STTrY. When the channel width is large, STTrY can drive a large on current. The channel semiconductor layer 50p may be separated in the X direction at an appropriate interval under the electrode 3, according to a necessary on current.

In FIG. 3, the electrode wiring lines 3 extending in the X direction, the gate electrodes STTGY of the Y selection transistors STTrY extending in the X direction, and the gate electrodes STTGX of the X selection transistors STTrX extending in the Y direction can be formed at a pitch of 2F with the minimum processing dimension as F. That is, memory cells of a projection area 4F² in an XY plane can be formed.

Here, structures of the selection transistors STTrX and STTrY will be described. If attention is paid to STTrY, the channel semiconductor layers 50p are formed on the sidewalls of the gates STTGY extending in the X direction and arranged in the Y direction at the pitch of 2F, with the gate insulating films therebetween. If attention is paid to one channel semiconductor layer 50p, both surfaces of the Y direction thereof contact STTGY with the gate insulating films therebetween. In addition, if attention is paid to one STTGY, both surfaces of the Y direction thereof contact the channel semiconductor layer 50p with the gate insulating films therebetween. When the thickness of the Y direction of the channel semiconductor layer 50p of the Y selection transistor STTrY is large (about 10 nm or more in the case of silicon), an independent inversion layer is formed in each of two STTGYs contacting the channel semiconductor layer with the gate insulating film therebetween. As a result, when an on voltage is applied to any one of the two gates or both the two gates, the channel semiconductor layer 50p is turned on and the plate-like electrode BEPLATE and the electrode 3 (MLR) are electrically connected. When an off voltage is applied to both the two gates, the channel semiconductor layer 50p is turned off and the plate-like electrode BEPLATE and the electrode 3 (MLR) are electrically insulated. In this case, if an on voltage is applied to one STTGY, the two channel semiconductor layers 50p at both sides thereof are turned on. For this reason, a selection operation for causing only one of the channel semiconductor layers 50p to be turned on is disabled.

However, in the case in which the channel semiconductor layer 50p is sufficiently thin (the thickness is preferably 5 nm or less in the case of silicon), even though an on voltage is applied to one of STTGYs at both sides, a strong off voltage (negative voltage with a source potential as a reference, in the case of an NMOS) is applied to the other, so that the other can be turned off. This is because a depletion layer spreads completely in a film thickness direction of the channel semiconductor 50p and a carrier density of the inversion layer of the back surface side of the channel semiconductor 50p is controlled by an electric field from one STTGY. Therefore, even if an on voltage is applied to one STTGY, the channel semiconductor layers 50p of both sides are not necessarily turned on and the channel semiconductor layers 50p can be turned off by applying a strong off voltage to the other STTGY contacting the channel semiconductor layer with the gate insulating film therebetween. By using this phenomenon, it is possible to select only one channel semiconductor layer and cause the channel semiconductor layer to be turned on. The plurality of channel semiconductor layers 50p to be continuous in the Y direction can be turned on at the same time. However, a specific selection state such as turning on the channel semiconductor layer for every other channel semiconductor layer is difficult. This is applicable to STTGX. In the semiconductor storage device of FIG. 3, the channel semiconductor layers 50p and 51p are formed of silicon and the film thickness of the Y direction of the channel semiconductor layer 50p and the film thickness of the X direction of the channel semiconductor layer 51p are set to about 5 nm or less.

FIG. 4 (a) is a diagram illustrating an extraction result of a part of the memory cell array according to the first embodiment. Components of PCMCHAIN, that is, the gate polysilicon layers 21p to 24p, the insulating films 11 to 15, a gate insulating film 9, the channel polysilicon layer 8p, an N-type polysilicon layer 25p, a phase change material 7, and insulating films 91 and 92 omitted to facilitate understanding in FIGS. 2 and 3 are also illustrated. In addition, gate insulating films GOX1_X and GOX2_X of STTrX are also illustrated. In addition, a cross-sectional view (FIG. 4 (b)) taken along line A-A′ in one gate polysilicon layer 21p and an equivalent circuit diagram (FIG. 4 (c)) corresponding to a part of the memory cell array are illustrated.

An operation of the memory cell can be executed as follows, for example. 0 V is applied to a gate line GL1 to which a selection cell SMC is connected and a transistor using the channel polysilicon layer 8p as a channel is turned off. 7 V is applied to gate lines GL2, GL3, and GL4 to which non-selection cells USMCs are connected and transistors are turned on. 0 V is applied to TEPLATE. When the reset operation and the set operation are executed, STTrX and STTrY are turned on and a reset voltage VRESET (for example, 5V) and a set voltage (for example, 4 V) are applied to BEPLATE. MLR enters a floating state. In the non-selection cell USMC, resistance of the channel becomes low in a state in which the transistor is turned on. For this reason, a current flows through the channel polysilicon layer 8p. Almost the same current can flow without depending on a state of the phase change material 7 in a USMC portion. In SMC, because the transistor is turned off, the current flows through the phase change material 7. When the reset operation and the set operation are executed, a resistance value of the phase change material 7 is changed by the current flowing through the phase change material 7 in SMC and the operation is executed.

When the read operation is executed, STTrX is turned on, STTrY is turned off, and 1 V is applied to MLR. In the non-selection transistor USMC, the resistance of the change becomes low in a state in which the transistor is turned on. For this reason, the current flows through the channel polysilicon layer 8p. Almost the same current can flow without depending on the state of the phase change material 7 in the USMC portion. In SMC, because the transistor is turned off, the current flows through the phase change material 7. A value of the current flowing through the phase change material 7 in SMC is detected using a sense circuit connected to MLR and the read operation is executed.

As the phase change material layer 7, a material such as Ge₂Sb₂Te₅ storing information using a characteristic that a resistance value in an amorphous state and a resistance value in a crystalline state are different can be used. An operation for changing a state from the amorphous state to be a high resistance state to the crystalline state to be a low resistance state, that is, the set operation is executed by heating the phase change material of the amorphous state to a crystalline temperature or more, maintaining this state for about 10⁻⁶ seconds or more, and causing the phase change material to enter the crystalline state. The phase change material of the crystalline state can enter the amorphous state by heating the phase change material to a temperate of a melting point or more, changing the state of the phase change material to a liquid state, and cooling the phase change material rapidly.

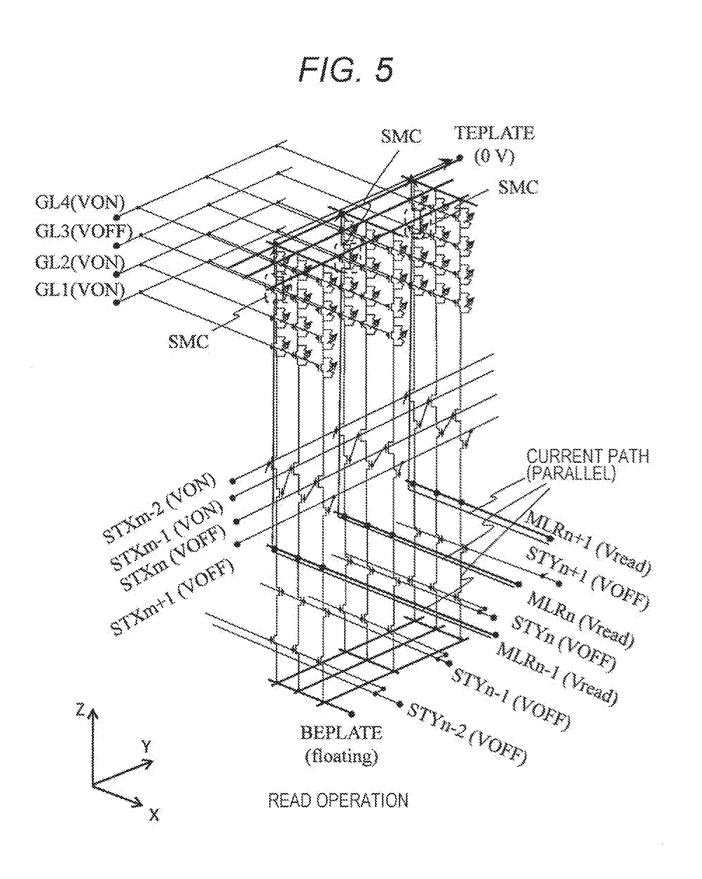

FIGS. 5 to 7 are equivalent circuit diagrams of the semiconductor storage device of FIG. 3 and illustrate the read operation, the set operation, and the reset operation, respectively. In the X selection transistor STTrX and the Y selection transistor STTrY, the channel semiconductor layers 51p and 50p are thin films of about 5 nm. For this reason, the X selection transistor STTrX and the Y selection transistor STTrY are turned on when an on voltage is applied to the gates of both sides and are turned off when a strong off voltage is applied to the other gate even though an on voltage is applied to one gate. Because these are illustrated as equivalent circuits, in FIGS. 5 to 7, each of the Y selection transistor STTrY and the X selection transistor STTrX is shown by two transistors connected in series and facing transistors are connected in series.

FIG. 5 illustrates the read operation using the equivalent circuit diagram. In the read operation, all of the Y selection transistors STTrY are turned off and electrically insulate the plate electrode BEPLATE and the electrode 3 (MLR). A current between the electrode wiring line 3 (MLR) and TEPLATE at both sides of PCMCHAIN is detected, so that it is determined whether the selection memory cell SMC is in the set state of the low resistance or the reset state of the high resistance. The current flowing at that time is set to a small current of a degree where the resistance state of the phase change memory does not change, that is, a current sufficiently smaller than the set current and the reset current, so that non-destructive read is enabled. The electrode wiring lines 3 are arranged at the same pitch as PCMCHAIN in the Y direction and are connected to resistance sense circuits on the semiconductor substrate. For example, each electrode wiring line 3 is connected to the independent sense circuit, so that one cell can be selected from each of the plurality of PCMCHAINs arranged in the Y direction as illustrated in FIG. 5, and parallel read is enabled.

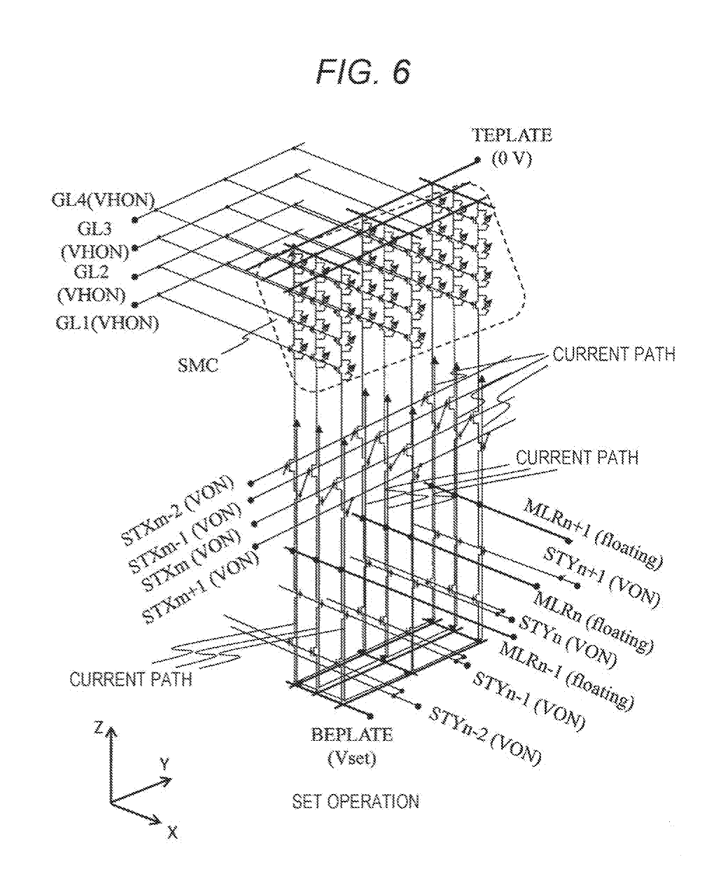

FIG. 6 illustrates the set operation using the equivalent circuit diagram. In the set operation, the electrode 3 and the sense circuit are insulated by a peripheral circuit. That is, the electrode 3 is insulated from elements other than STTrX and STTrY contacting the electrode 3 on and below the electrode 3. Different from the read operation, the set operation is executed by causing a current to flow between BEPLATE and TEPLATE via PCMCHAIN and generating a Joule heat in PCMCHAIN. If the set operation is executed by causing a current to flow in parallel to the plurality of PCMCHAINs adjacent to each other, simultaneously selecting all cells in each PCMCHAIN, and generating a heat (bundle erasure), the heat is transmitted between PCMCHAINs. For this reason, multiple cells per unit consumption power can be set as compared with a method in which each memory cell is selected and the set operation is executed or a method in which the current flows through each PCMCHAIN and the set operation is executed. That is, a transfer speed of the erasure can be improved. FIG. 6 illustrates the case in which the set operation is executed by causing the current to flow to three continuous PCMCHAINs in each of the X and Y directions, that is, a total of nine PCMCHAINs. To execute the set operation at a high speed, a method in which the set operation is collectively executed, a collective erasure operation is executed, and write is performed on each cell in the reset operation to be described below is used. In a resistance change type memory including the phase change memory, when the set operation is executed, it is necessary to cause the current to flow to the resistance change element. For this reason, when the resistance of the memory cell increases excessively at the time of the reset operation to be described below, the current may not be caused to flow sufficiently thereafter and the set operation may not be executed or it may be necessary to apply a high voltage as compared with a normal set operation to cause the current to flow. In PCMCHAIN, each memory cell has a configuration in which the phase change material layer and the cell transistor are connected in parallel and the individual memory cells are connected in series. For this reason, when the set operation is executed, a current flowing through PCMCHAIN has a component flowing through the phase change material layer and a component flowing through the cell transistor. Because the set operation is executed in about one microsecond, the Joule heat generated in the channel of the cell transistor is transmitted to the phase change material layer contacting the channel. If an appropriate on voltage (half-on voltage: VHON) is applied to the gate of the cell transistor, the channel is controlled in an appropriate on resistance state, and a potential difference is applied between WLPLATE and BLPLATE, the Joule heat generated in the channel portion is transmitted to the phase change material layer and the set operation can be executed. For this reason, even if the resistance of the phase change material layer is increased excessively by the reset operation or a large voltage is applied to the memory cell and the current is caused not to flow, the set operation can be executed. VHON illustrated in FIG. 6 exemplifies this operation.

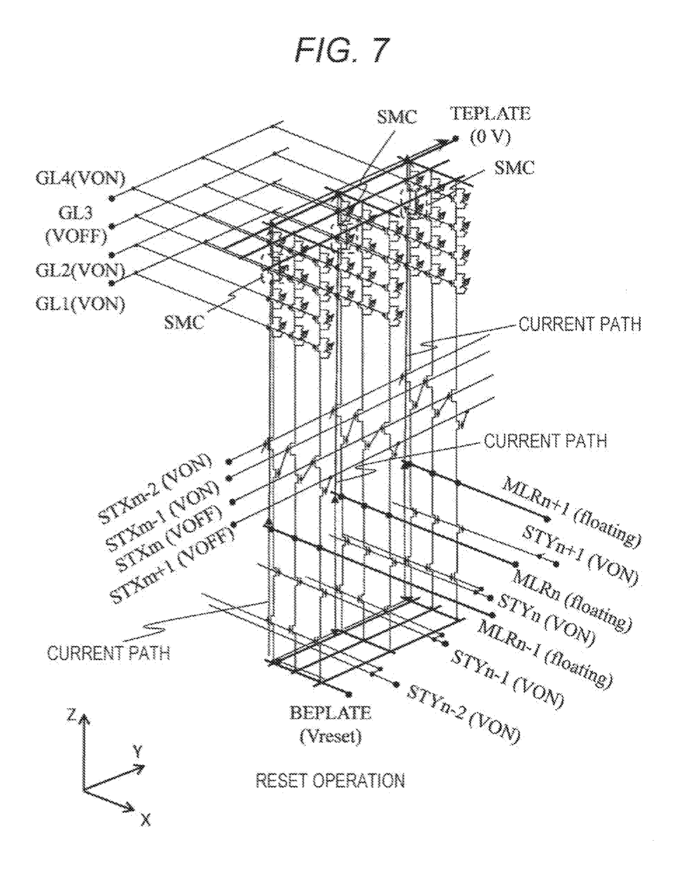

FIG. 7 illustrates the reset operation using the equivalent circuit diagram. In the reset operation, similar to the set operation, the electrode 3 and the sense circuit are insulated by the peripheral circuit. That is, the electrode 3 is insulated from elements other than STTrX and STTrY contacting the electrode 3 on and below the electrode 3. Similar to the set operation, the reset operation is executed by causing a current to flow between BEPLATE and TEPLATE via PCMCHAIN. Because the collective erasure operation is executed in the set operation, but a data write operation is executed in the reset operation, the operation is selectively executed on each memory cell. The X selection transistor STTrX connected to the selected PCMCHAIN and the Y selection transistor STTrY connected via the electrode 3 are turned on, an off voltage is applied to the gate of the cell transistor of the selection cell of PCMCHAIN, and an on voltage is applied to the gate of the cell transistor of the non-selection cell of PCMCHAIN. In this state, if a potential difference is applied between BEPLATE and TEPLATE, the current flows through the phase change material layer of the selection cell SMC. A voltage between BEPLATE and TEPLATE is configured as a pulse shape of about 10 ns and falls steeply in particular, so that a state of the phase change material layer of SMC can be changed from the crystalline state (set state) of the low resistance to the amorphous state (reset state) of the high resistance, similar to the normal phase change memory. Similar to the set operation, only one PCMCHAIN can be selected between the plate electrodes BEPLATE and TEPLATE. However, a plurality of PCMCHAINs can be selected. This is because it is not necessary to detect a current flowing through each PCMCHAIN, different from the read operation.

Because it is necessary to decrease the thickness of the semiconductor channel layers 50p and 51p to about 5 nm, STTrX and STTrY are manufacture as follows. For STTrY, a contact is formed from the lower side with respect to the gate STTGY.

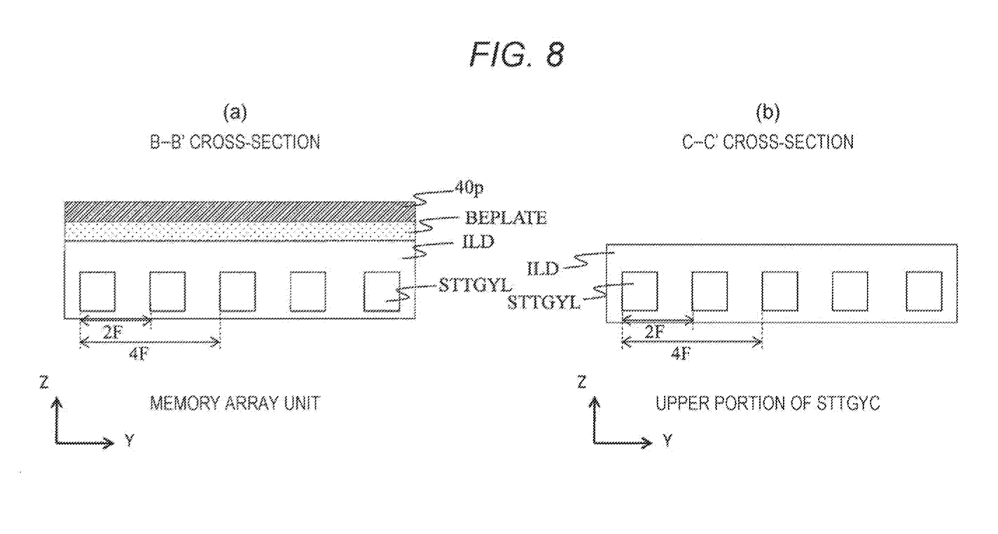

A method of manufacturing the semiconductor storage device according to the first embodiment will be described using FIGS. 8(a) to 22. In FIGS. 8(a) to 19(b), a cross-section (a) taken along line B-B′ in the memory array unit on the lower electrode BEPLATE on the wiring line STTGYL illustrated in FIG. 3 in each process and a cross-section (b) taken along line C-C′ in the STTGYC portion to feed the gate electrode STTGY illustrated in FIG. 2 are illustrated in parallel.

After an interlayer insulating film IDL is formed on the semiconductor substrate on which the circuit to drive the semiconductor storage device and the wiring line STTGYL to feed STTGY are formed, BEPLATEC is formed, a metal film becoming BEPLATE, for example, a lamination film of tungsten and titanium nitride is formed, and the N-type polysilicon layer 40p is formed on the titanium nitride. A formed pattern is processed by known lithography and dry etching technology and BEPLATE is formed (FIGS. 8(a) and 8 (b)).

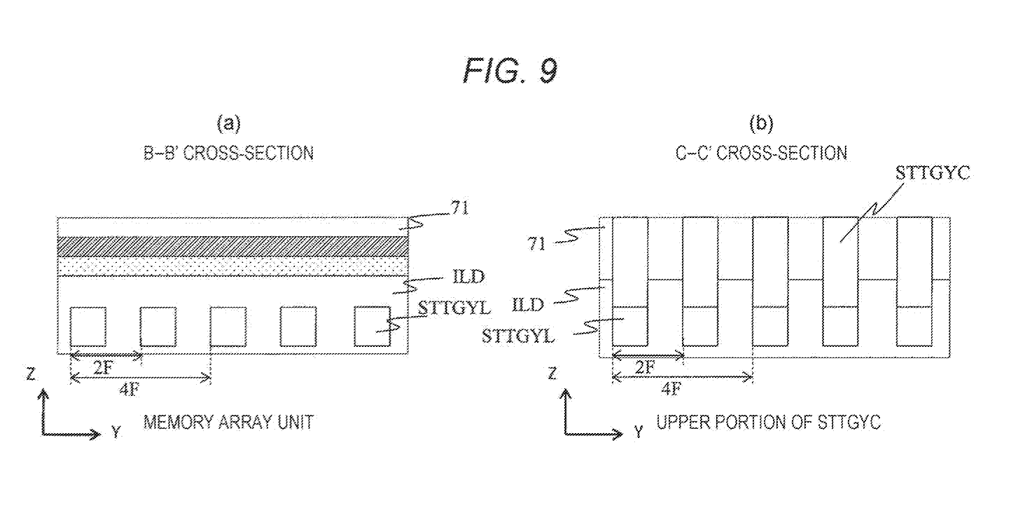

After an insulating film 71 (for example, a silicon nitride film or a silicon oxide film) to separate BEPLATE and STTGY is formed, a space portion of BEPLATE is provided with STTGYC to electrically connect STTGYL and STTGY formed thereon (FIGS. 9(a) and 9 (b)). When STTGYC is formed, formation of a hole pattern for the interlayer insulating film using known lithography and dry etching technology, formation of the metal film using a chemical vapor deposition method (CVD method), and a chemical mechanical polishing method (CMP method) can be used. STTGYC is formed at the pitch of 2F in the Y direction, for example.

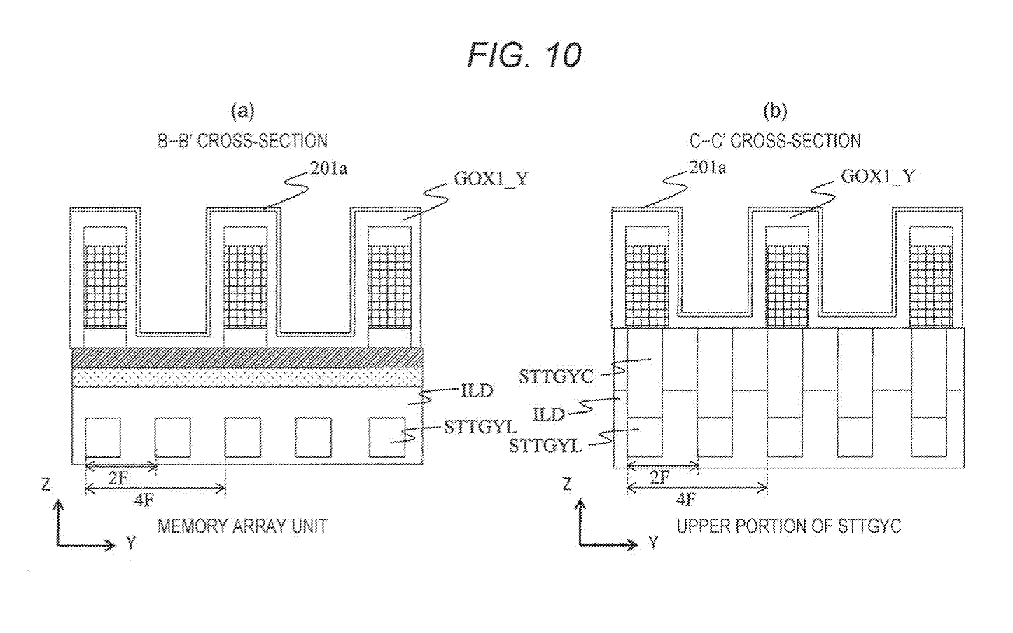

After an N-type polysilicon layer 101p becoming STTGY and the insulating film 72 (for example, a silicon nitride film or a silicon oxide film) are formed on the insulating film 71, patterning is performed (FIGS. 10(a) and 10 (b)). In FIGS. 10(a) and 10 (b), in processing of the insulating film 72 and the N-type polysilicon layer 101p is simultaneously performed, the BEPLATE portion and the BEPLATE space portion are simultaneously processed and in processing of the insulating film 71, only the BEPLATE space portion is covered with a resist and only the BEPLATE portion is processed. At this time, 101p extending in the X direction is formed at the pitch of 4F in the Y direction, with the minimum processing dimension as F. For example, a width of the Y direction of 101p is set to F, a width of the space is set to 3F, and patterning is performed. 101p formed at the pitch of 4F in the Y direction forms a contact covering STTGYC formed at the pitch of 2F in the Y direction for every other STTGYC in the Y direction.

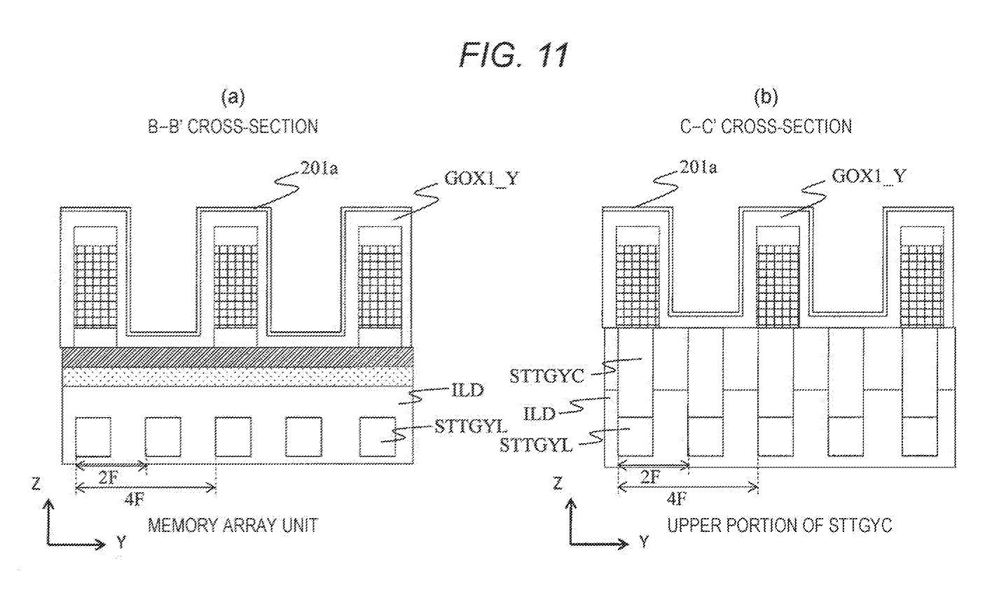

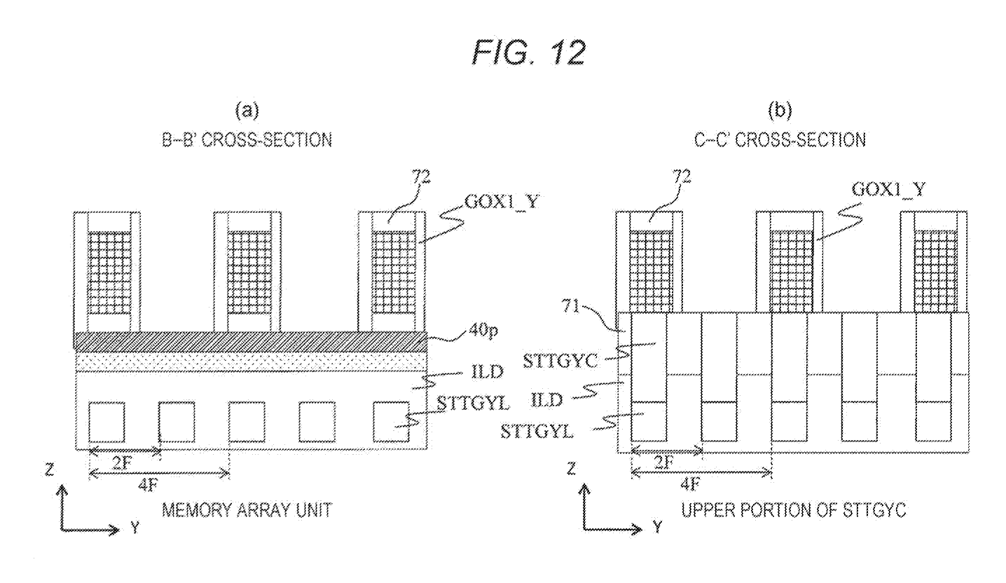

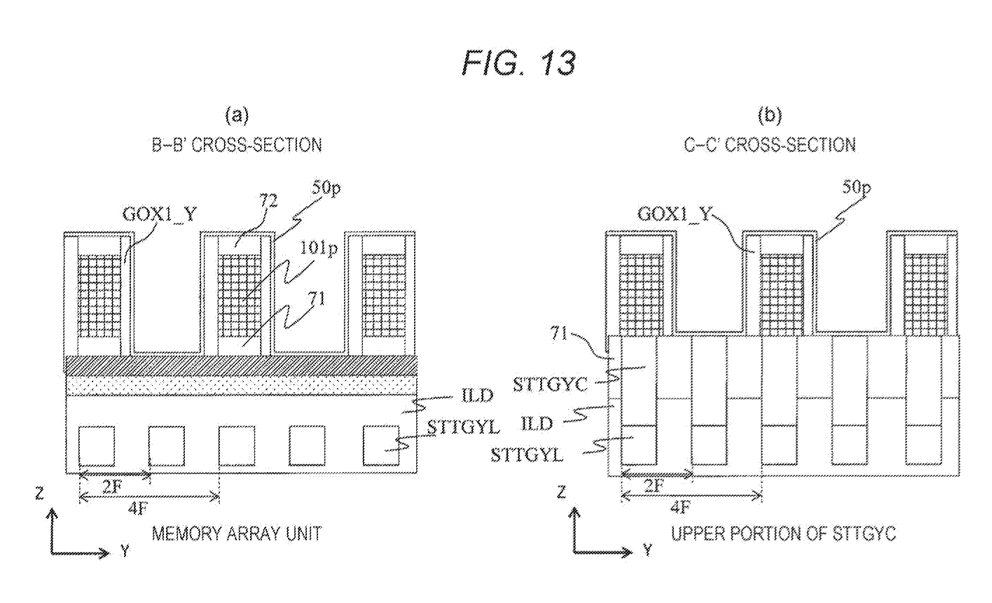

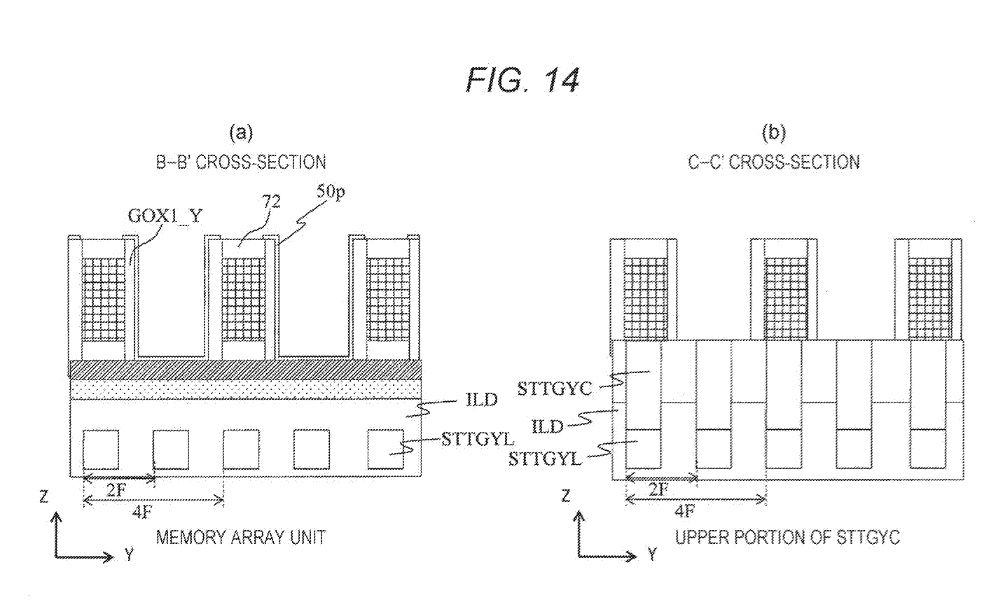

Next, a gate insulating film (for example, a silicon oxide film) GOX1_Y is formed not to completely bury the space between 101p formed at the pitch of 4F and an amorphous silicon layer 201a becoming a protective film is formed (FIGS. 11(a) and 11 (b)). After a top surface of a pattern of the insulating film 72, the amorphous silicon layer 201a of a groove bottom portion of a pattern of 101p, and the gate insulating film GOX1_Y are removed by etch-back processing, the amorphous silicon layer 201a is removed by wet etching (FIGS. 12(a) and 12 (b)). When the etch-back processing is executed, the gate insulating film GOX1_Y of the sidewall of 101p is protected by the amorphous silicon layer 201a. Therefore, reliability of the gate insulating film GOX1_Y can be secured as compared with the case in which the amorphous silicon layer 201a is not provided. Next, the silicon layer 50p becoming the channel semiconductor layer is formed not to completely bury a groove space between STTGY (FIGS. 13(a) and 13 (b)). As described above, the thickness of 50p is preferably about 5 nm or less. The film thickness of 5 nm can be easily realized by formation of a silicon layer of a single layer. 50p is patterned, 50p is separated at the top surface of the pattern of the insulating film 72, and 50p is removed on STTGYC not covered with 101p (FIGS. 14(a) and 14 (b)).

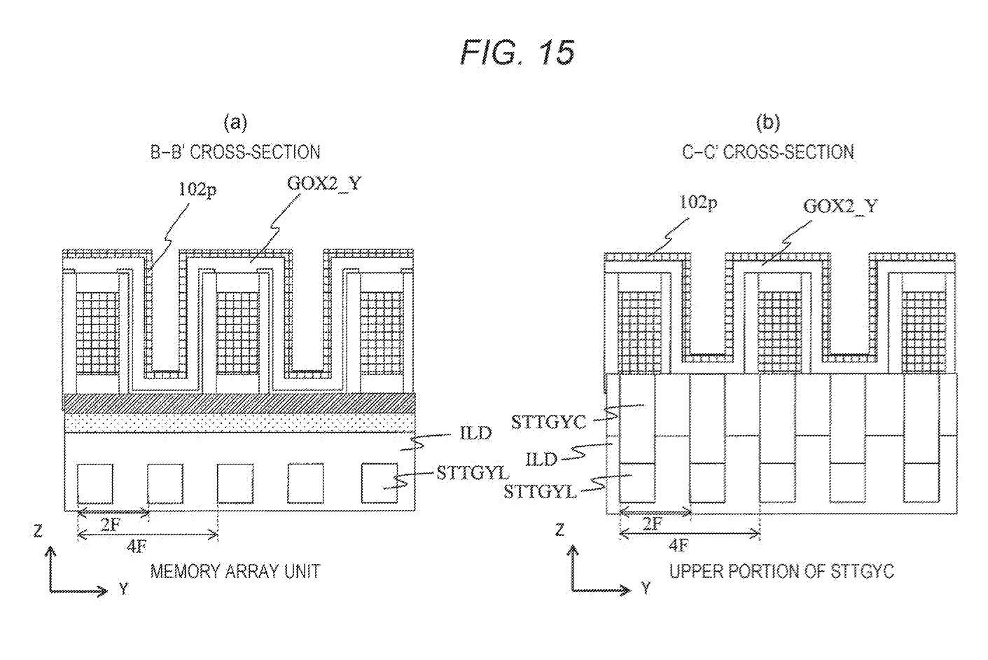

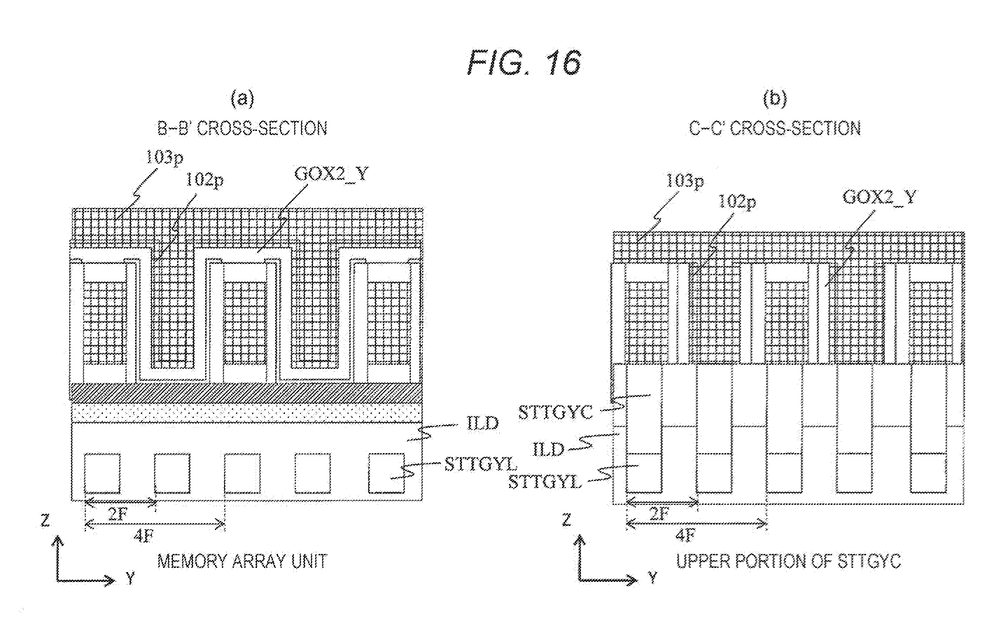

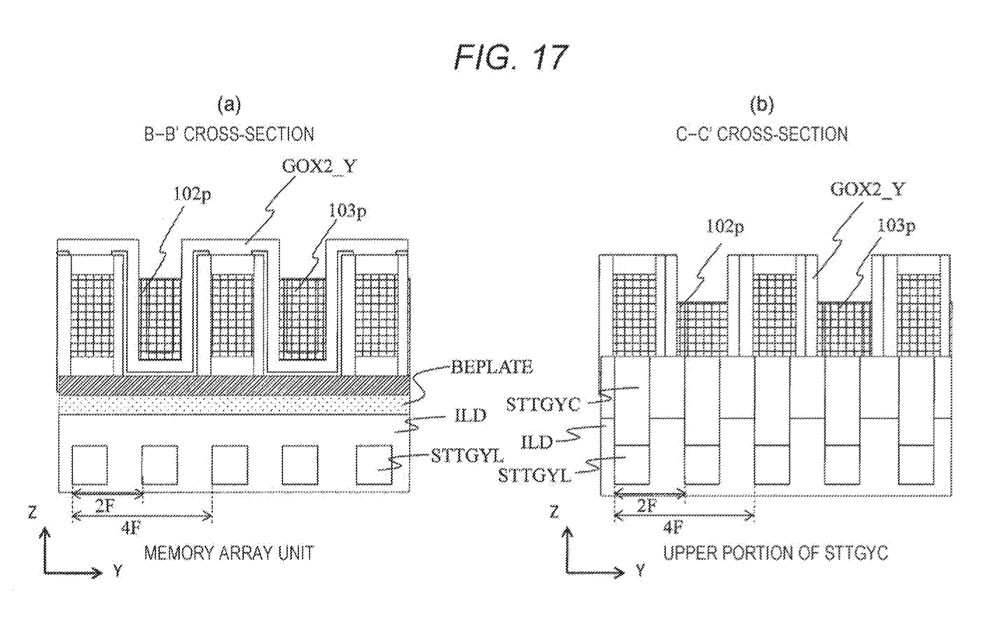

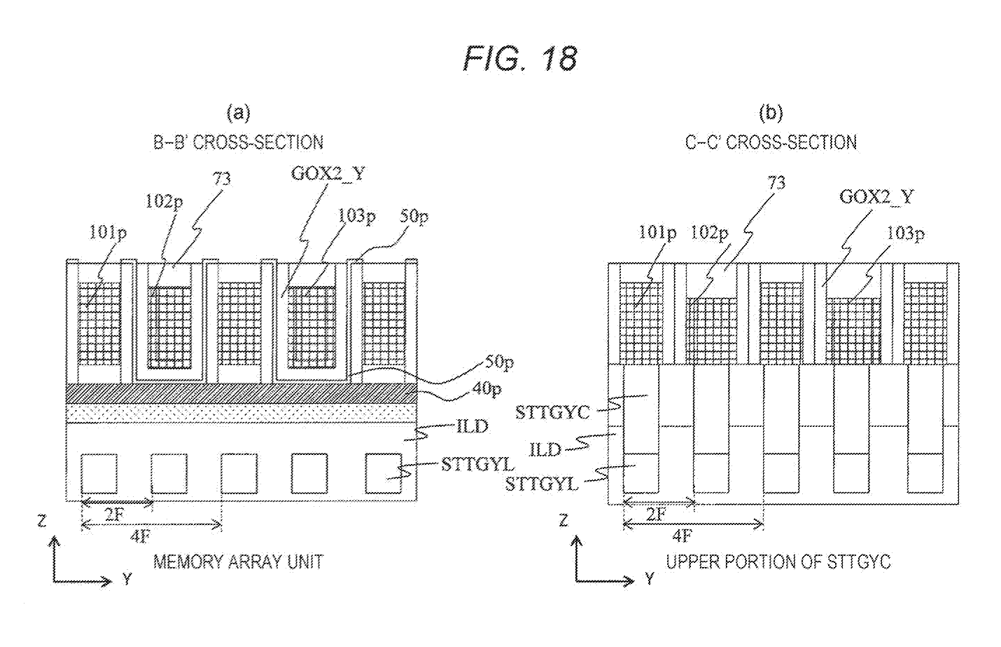

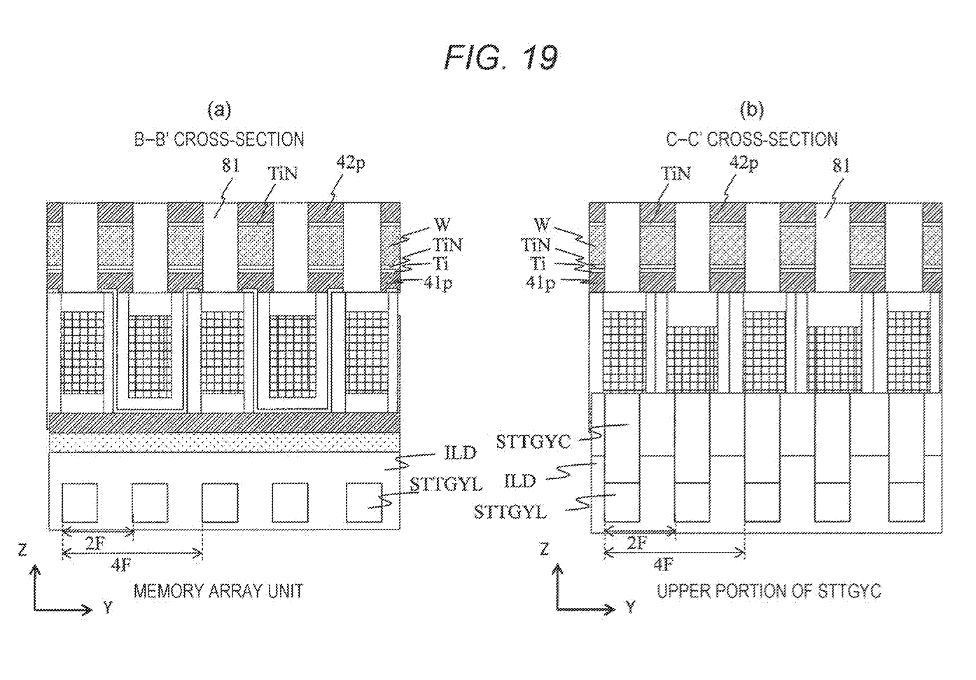

Next, a gate insulating film (for example, a silicon oxide film) GOX2_Y is formed and an N-type polysilicon layer 102p becoming a portion of the gate STTGY is formed (FIGS. 15(a) and 15 (b)). Next, GOX2_Y and 102p covering STTGYC are removed by the dry etching by covering the BEPLATE portion with a resist, STTGYC is exposed, and an N-type polysilicon layer 103p becoming apart of STTGYC is formed. 103p and STTGYC are connected (FIGS. 16(a) and 16 (b)). Upper portions of 102p and 103p are removed by the etch-back processing and patterns of 102p and 103p are separated (FIGS. 17(a) and 17 (b)).

Here, 102p and 103p use the same N-type polysilicon as 101p. However, materials different from a material of 101p may be used in 102p and 103p. For example, after the process of FIGS. 17(a) and 17(b)), silicide processing can be executed in a self-matching manner on 102p and 103p using Ti, Ni, and Co. In this way, because the resistance of the gate electrode including 102p and 103p can be decreased, resistance of 101p can be decreased by decreasing dimensions of the X direction of 102p and 103p and increasing a dimension of the X direction of 101p. In addition, the same material does not need to be used in the gate insulating films GOX1_Y and GOX2_Y and one can be configured as a silicon oxide film and the other can be configured as a High-K film. In addition, GOX1_Y and GOX2_Y can be formed to the have the different thickness.

As seen from FIGS. 17(a) and 17(b), the thickness of 101p is the same on BEPLATE and STTGYC. However, the thickness of 102p and 103p is different on BEPLATE and STTGYC and is small on STTGYC. This is because the insulating film 71 is not removed on STTGYC and a depth of a groove formed by the process of FIGS. 10(a) and 10(b) is small as compared with BEPLATE. It is concerned about resistance becoming higher. However, this can be resolved by decreasing resistance by executing the silicide processing on 102p and 103p, as described above.

Next, after an insulating film 73 is formed, an upper portion is retreated and an upper portion of the channel polysilicon layer 50p is exposed (FIGS. 18(a) and 18(b)).

In this step, the gates STTGY (101p, 102p, and 103p) of the Y selection transistors are formed at the pitch of 2F in the Y direction. If attention is paid to two to be continuous in the Y direction, one includes 101p and the other includes two layers of 102p and 103p. All the gates are connected to STTGYC at the lower side. A width (thickness of a film interposed by the gate insulating films GOX1_Y and GOX2_Y) of the Y direction of the channel silicon layer 50p can be determined by the thickness of the film not depending on the minimum processing dimension. For this reason, the width can be set to 5 nm, even though high expensive lithography such as extreme ultraviolet (EUV) lithography is not used.

As apparent from FIGS. 18(a) and 18(b), the channel silicon layers 50p of both sides of the gate including 102p and 103p are connected via the portion below the gate including 102p and 103p. The N-type polysilicon layer 40p to be the lower electrode and the channel silicon layer 50p contact at the portion below the gate including 102p and 103p. For this reason, a contact area between the N-type polysilicon layer 40p and the channel silicon layer 50p can be greatly secured as compared with the case in which the channel silicon layer 50p is separated at the portion below the gate including 102p and 103p. Therefore, contact resistance can be reduced.

Even when the channel silicon layer 50p needs to be separated at the portion below the gate including 102p and 103p, it is preferable to secure the contact area with the N-type polysilicon layer 40p by minimizing a separation width thereof.

To reduce contact resistance of the channel silicon layer 50p and the N-type polysilicon layer 41p to be described below and becoming the upper electrode on the channel silicon layer 50p, it is preferable to increase a contact area with the upper electrode by a structure in which a part of the channel polysilicon layer 50p is stranded on the gate side including 101p.

Next, the N-type polysilicon layer (42p)/titanium nitride layer/tungsten layer/titanium nitride layer/titanium layer/N-typepolysilicon layer (41p) becoming the wiring lines MLR for the read are formed sequentially from the lower layer and are separated into patterns extending in the X direction. The pitch of the Y direction is 2F equal to the pitch of STTGY. After a space between the read wiring lines MLR is buried with an insulating film 81, the N-type polysilicon layer 42p is exposed by the CMP method (FIGS. 19(a) and 19(b)).

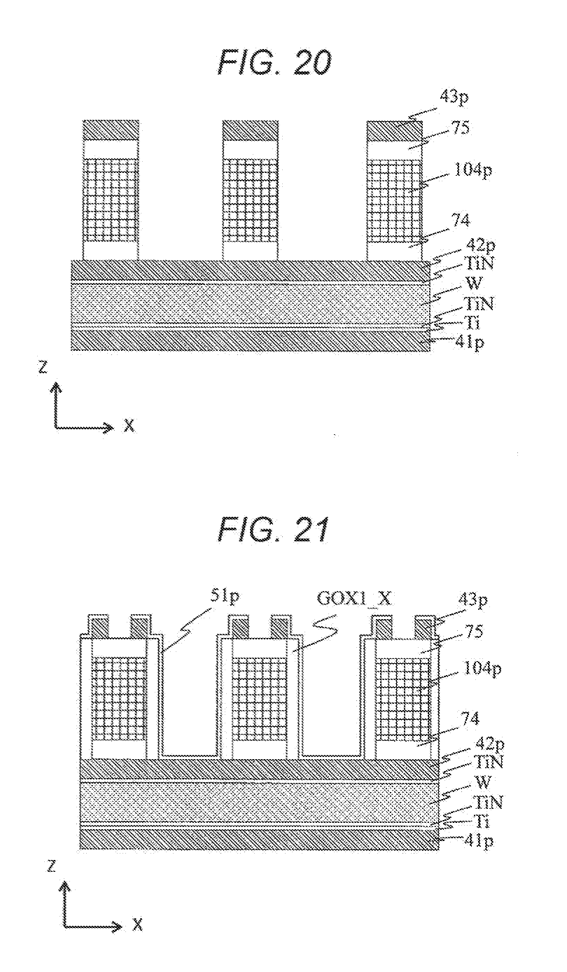

Next, after an insulating film 74 (for example, a silicon nitride film or a silicon oxide film) to separate MLR and STTGX is formed, an N-type polysilicon layer 104p becoming STTGX, an insulating film 75 (for example, a silicon nitride film or a silicon oxide film), and an N-type polysilicon layer 43p are formed and patterning of the insulating film 75, the N-type polysilicon layer 104p, the insulating film 74, and the N-type polysilicon layer 43p is performed. At this time, the patterns extending in the Y direction are formed at the pitch of 4F in the X direction, with the minimum processing dimension as F. For example, the width of the X direction of 104p is set slightly larger than F, the width of the space is set slightly smaller than 3F, and patterning is performed (FIG. 20).

Next, the gate insulating film (for example, the silicon oxide film) GOX1_X is formed not to completely bury the space between 104p formed at the pitch of 4F and the amorphous silicon layer 202a becoming the protective film is formed. After a top surface of a pattern of the insulating film 75, an amorphous silicon layer 202a of a groove bottom portion between patterns of 104p, and the gate insulating film GOX1_X are removed by the etch-back processing, the amorphous silicon layer 202a is removed by the wet etching. When the etch-back processing is executed, the gate insulating film GOX1_X of the sidewall of 104p is protected by the amorphous silicon layer 202a. Therefore, reliability of the gate insulating film GOX1_X can be secured as compared with the case in which the amorphous silicon layer 202a is not provided.

Next, the silicon layer 51p becoming the channel is formed not to completely bury a space between STTGX (104p). Next, 51p is patterned, 51p is separated on the pattern of the insulating film 75, and 51p is separated in the X direction at the pitch of 2F. At this time, the N-type polysilicon layer 43p is also processed on the top surface of the insulating film 75 (FIG. 21). The N-type polysilicon layer 43p functions as a source/drain diffusion layer of the channel semiconductor layer of the X selection transistor STTrX. The N-type diffusion layer 43p is not necessarily formed. That is, N-type impurities may be implanted into a portion on the channel semiconductor layer 51p and the N-type polysilicon layer may be formed on the channel semiconductor layer 51p. A method of forming the N-type polysilicon layer 43p can be used when the Y selection transistor STTrY is manufactured.

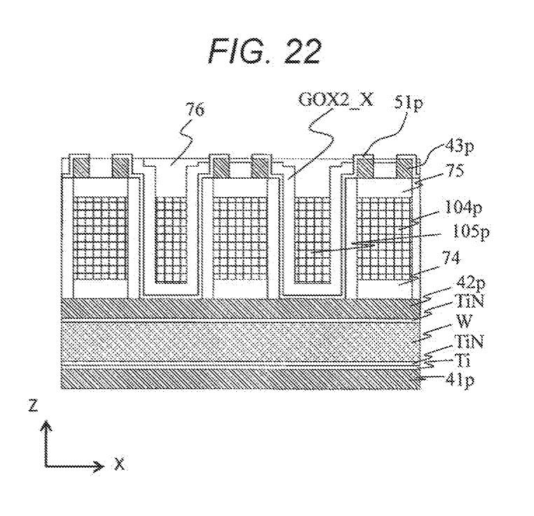

Next, the gate insulating film (for example, a silicon oxide film) GOX2_X is formed and an N-type polysilicon layer 105p becoming the gate STTGX is formed. An upper portion of 105p is removed by the etch-back processing and a pattern of 105p is separated. After an insulating film 76 is formed, the upper portion is retreated and the upper portion of the channel polysilicon layer 51p is exposed (FIG. 22).

In this step, STTGX is formed at the pitch of 2F in the X direction. If attention is paid to two to be continuous in the X direction, one includes 104p, the other includes 105p, and shapes thereof are different. A width (thickness of a film interposed by the gate insulating films GOX1_X and GOX2_X) of the X direction of the channel silicon layer 51p can be determined by the thickness of the film not depending on the minimum processing dimension. For this reason, the width can be set to 5 nm, even though the high expensive lithography such as the extreme ultraviolet (EUV) lithography is not used.

Even in a structure of FIG. 22, similar to the description of FIGS. 18(a) and 18(b), the channel silicon layers 51p of both sides of the gate including 105p are connected via the portion below the gate including 105p. The N-type polysilicon layer 42p to be the lower electrode and the channel silicon layer 51p contact at the portion below the gate including 105p. For this reason, a contact area between the N-type polysilicon layer 42p and the channel polysilicon layer 51p can be greatly secured as compared with the case in which the channel silicon layer 51p is separated at the portion below the gate including 105p. Therefore, contact resistance can be reduced.

Even when the channel silicon layer 51p needs to be separated at the portion below the gate including 105p, it is preferable to secure the contact area with the N-type polysilicon layer 42p by minimizing a separation width thereof.

STTGY formed after the contact STTGYC to feed STTGY and STTGYL connected to STTGYC are formed below a formation position of STTGY is formed with the two layers of 102p and 103p. However, because the contact STTGXC to feed STTGX and STTGXL connected to STTGXC is formed on STTGX, STTGX formed after STTGX is formed of the layer of 104p can be formed with the single layer of 105p. The contact can formed from the lower portion side using the same process as STTGY when STTGX is formed.

Then, as illustrated in FIG. 4 (a), after the N-type diffusion layer is formed on 51p, the insulating films 11, 12, 13, 14, and 15, the N-type polysilicon layers 21p, 22p, 23p, and 24p becoming the memory cell gates, and the N-type polysilicon layer 25p becoming the upper electrode are alternately laminated and form a laminate. Then, the memory cell and the upper electrode are formed and the gate electrodes GATE1 (21p), GATE2 (22p), GATE3 (23p), and GATE4 (24p) of the memory cells are processed using the known technology. After the interlayer insulating film is formed, the contact STTGXC to feed STTGX, STTGXL connected to STTGXC, the gate electrodes GATE1, GATE2, GATE3, and GATE4 of the memory cells, and the contact to the wiring line MLR for the read are formed, the wiring line connected to the peripheral circuit is formed, and the semiconductor storage device is finished.

In the finished semiconductor storage device, because the memory cells can be formed at the pitch of 2F in both the X direction and the Y direction, a large capacity and reduction of a bit cost are enabled. In addition, the finished semiconductor storage device is applied to an information processing device such as storages and servers, so that the information processing device can realize performance improvement using a storage device having a low cost and a large capacity.

### Second Embodiment

In the first embodiment, the phase change memory is used. However, a selection transistor according to the present invention can be used in other memory. In this embodiment, the case in which a flash memory is used is illustrated.

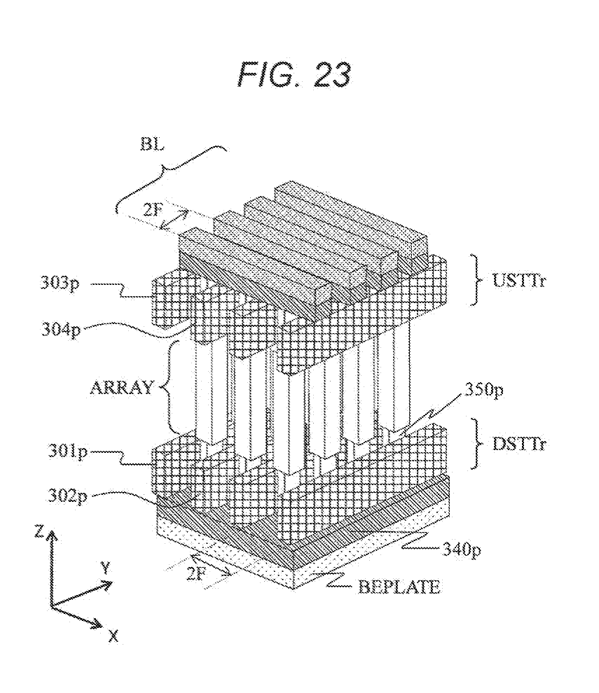

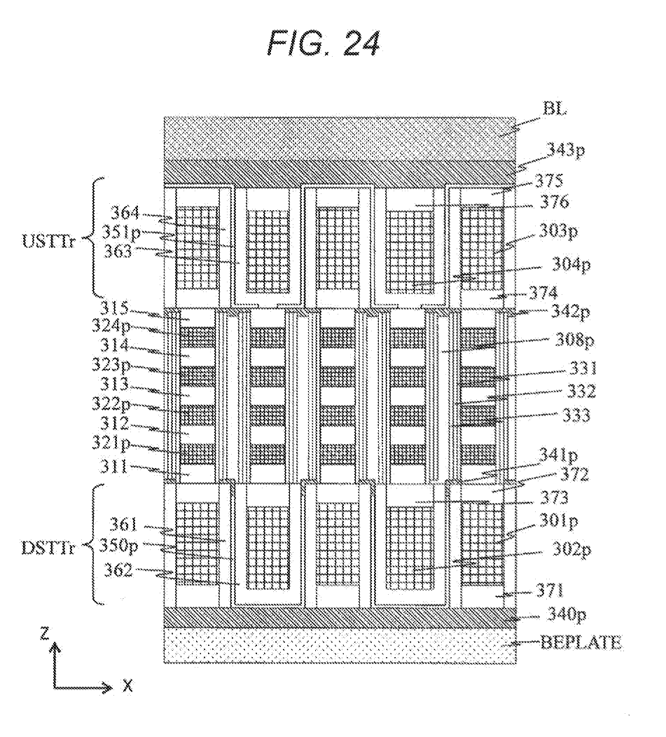

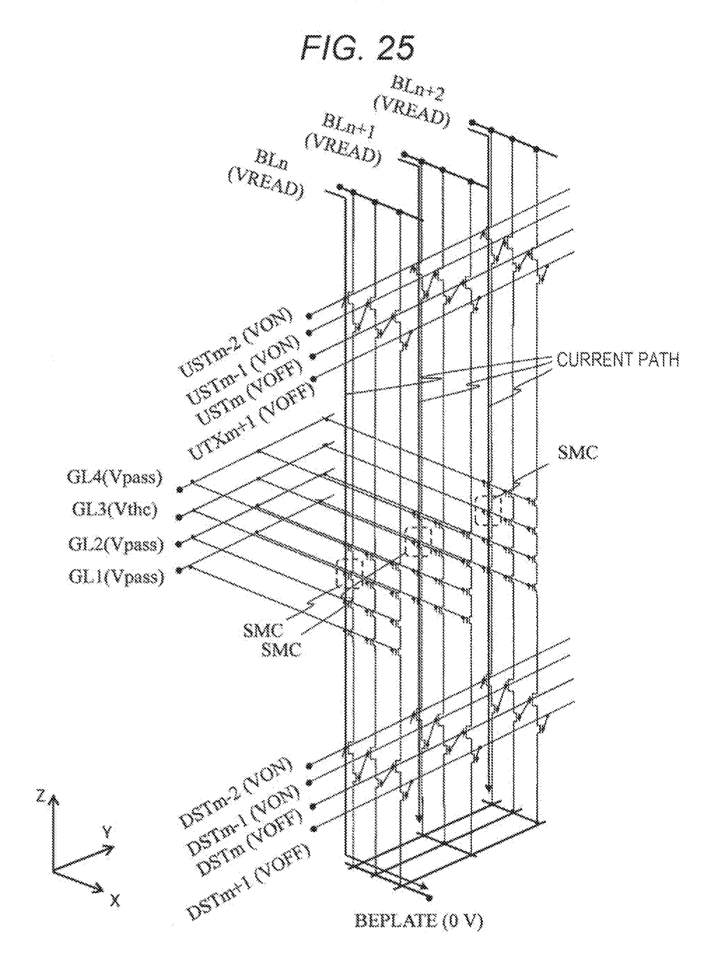

FIG. 23 illustrates a bird's eye view of a device structure of the flash memory using the selection transistor according to the present invention, FIG. 24 illustrates a cross-sectional view of an XZ plane, and FIG. 25 illustrates an equivalent circuit diagram. FIG. 25 illustrates a voltage condition of a read operation.

A flash memory array is connected to electrodes via the selection transistors at both ends. An operation method of the selection transistor is the same as that of the first embodiment.

FIG. 23 illustrates a lower electrode BEPLATE, lower selection transistors DSTTr extending in a Y direction, upper selection transistors USTTr extending in a Y direction, and upper electrode wiring lines BL extending in the X direction. The memory array is described using the next cross-sectional view. Memory holes are formed at a pitch of 2F in the X direction and the Y direction.

FIG. 24 illustrates a laminate in which electrode layers 321p, 322p, 323p, and 324p becoming gates and insulating films 311, 312, 313, 314, and 315 are alternately laminated, the memory holes of a Z direction formed in the laminate, and ONO films in the memory holes, that is, silicon oxide films (331)/silicon nitride films (332)/silicon oxide films (333) and channel semiconductor layers 308p, which are omitted in FIG. 23.

DSTTr is formed using gate electrodes 301p and 302p, insulating films 371, 372, and 373, gate insulating films 361 and 362, and channel semiconductor layers 350p. The channel semiconductor layers 350p are disposed such that the two channel semiconductor layers 350p adjacent to each other in the X direction are connected via a gate insulating film 362 below the gate electrode 302p and the channel semiconductor layers 350p contact an N-type semiconductor layer 340p to be a part of a lower electrode at a connection portion. Similar to the first embodiment, because a width of the X direction of a contact portion of 340p and 350p is larger than the film thickness of 350p, 340p and 350p can be contacted over a wide area. Therefore, contact resistance between 340p and 350p can be reduced. An N-type semiconductor layer 341p is formed on 350p and is connected to the channel semiconductor layer 308p of the memory cell array. An N-type semiconductor layer 342p is formed on the channel semiconductor layer 308p and is connected to a channel semiconductor layer 351p of USTTr.

USTTr is formed using gate electrodes 303p and 304p, insulating films 374, 375, and 376, gate insulating films 363 and 364, and channel semiconductor layers 351p. The channel semiconductor layers 351p are disposed such that the two channel semiconductor layers 351p adjacent to each other in the X direction are connected via the insulating film 375 on the gate electrode 303p and the channel semiconductor layers 351p contact an N-type semiconductor layer 343p to be a part of an upper electrode at a connection portion. Similar to the channel semiconductor layer 350p of DSTTr, because a width of the X direction of a contact portion of 343p and 351p is larger than the film thickness of 351p, 343p and 351p can be contacted over a wide area. Therefore, contact resistance between 343p and 351p can be reduced.

The channel semiconductor layers 350p are separated at a pitch of 2F equal to a pitch of the memory holes in the Y direction on elevations where there are sidewalls of at least the gate electrodes 301p and 302p.

The channel semiconductor layers 351p are separated at a pitch of 2F equal to the pitch of the memory holes in the Y direction. 351p separated in the Y direction is connected to the upper electrode BL that extends in the X direction and is formed at the pitch of 2F in the Y direction.

In the read operation, the lower selection transistor DSTTr including the selection cell and the channel semiconductor layer of the upper selection transistor USTTr are caused to enter a conductive state. In an example of FIG. 25, an on voltage is applied to DSTm−2 and DSTm−1 of gates DSTm−2, DSTm−1, DSTm, and DSTm+1 of DSTTr and an off voltage is applied to the remaining gates. An on voltage is applied to USTm−2 and USTm−1 of gates USTm−2, USTm−1, USTm, and USTm+1 of USTTr and an off voltage is applied to the remaining gates. As a result, one place of the X direction is selected. For the Z direction, a potential Vthc of a threshold determination level is applied to the gate electrode including the selection cell and a potential Vpass (for example, 6 V) where the channel semiconductor layer 308p of the cell is sufficiently turned on without depending on a threshold state of the cell is applied to the other gate electrodes. As a result, one place of the Z direction is selected. In a state in which one place of each of the X direction and the Z direction is selected, a potential of 0 V is applied to the lower electrode BEPLATE and a potential of 1 V is applied to the upper electrode BL. Because a plurality of BLs are formed in at a pitch of 2F in the Y direction, the plurality of BLs can be simultaneously selected in the Y direction. A current flowing through BL is detected and information is read according to whether a threshold Vth of the selection cell is higher or lower than Vthc.

A write operation is executed after an erasure operation to be described below is collectively executed. In the write operation, the lower selection transistor DSTTr is turned off and the channel semiconductor layer of the upper selection transistor USTTr connected to the selection cell is caused to enter a conductive state. As a result, one place of the X direction is selected. For the Z direction, a write potential (for example, +20 V) is applied to the gate electrode including the selection cell and the potential Vpass (for example, 10 V) where the channel semiconductor layer 308p of the cell is sufficiently turned on without depending on a threshold state of the cell is applied to the other gate electrodes. As a result, one place of the Z direction is selected. The lower electrode BEPLATE is set to 0 V, for example. In a state in which one place of each of the X direction and the Z direction is selected, a potential according to a data write pattern is applied to the upper electrode BL. Because the plurality of BLs are formed in at a pitch of 2F in the Y direction, the plurality of BLs can be simultaneously selected in the Y direction. In a place where electrons are implanted into the ONO film of the memory cell and write is performed, 0 V is applied to BL and 0 V is fed from BL to the channel semiconductor layer 308p via USTTr. Because a potential difference 20 V between +20 V of the selection gate and 0 V of the channel semiconductor layer 308p is applied to the ONO film of the selection cell, electrons are implanted into the ONO film from the channel semiconductor layer 308p and write is generated. In a place where an operation for implanting electrons into the ONO film of the memory cell and performing write is not executed, about 3 V is applied to BL, USTTr is turned off, and the channel semiconductor layer 308p and BL are separated. In this case, because a potential of 308p in a floating state becomes high (for example, 7 V) by the potential Vpass (for example, 10 V) of the non-selection cell gate, a potential difference between +20 V of the selection gate and 5 V of the channel semiconductor layer 308p applied to the ONO film of the cell connected to the selection gate becomes 13 V lower than 20 V. For this reason, electrons are rarely implanted into the ONO film from the channel semiconductor layer 308p. In this way, write according to data to be stored can be performed.

In the erasure operation, first, 0 V is applied to the gates 303p and 304p of USTTr and the gates 301p and 302p of DSTTr and about 5 V is applied to BEPLATE and BL, hot holes are generated in a BEPLATE side end portion of DSTTr and a BL side end portion of USTTr, an appropriate potential is applied to the gates 303p and 304p of USTTr and the gates 301p and 302p of DSTTr of a block to be erased, and the hot holes generated by turning on USTTr and DSTTr are implanted into the channel semiconductor layer 308p. A negative voltage (for example, −15 V) is applied to the gate electrodes 321p, 322p, 323p, and 324p, so that the holes are implanted into the ONO film to be a load accumulation film of the memory cell from the channel semiconductor layer 308p, and collective erasure is performed.

In the semiconductor storage device according to the second embodiment, because the memory cells can be formed at the pitch of 2F in both the X direction and the Y direction, a large capacity and reduction of a bit cost are enabled. In addition, the finished semiconductor storage device is applied to an information processing device such as storages and servers, so that the information processing device can realize performance improvement using a storage device having a low cost and a large capacity.

### Third Embodiment

In the first and second embodiments, the phase change memory and the flash memory are used, respectively. However, a selection transistor according to the present invention can be used in other memory. In this embodiment, the case in which a vertical cross point memory is used is illustrated.

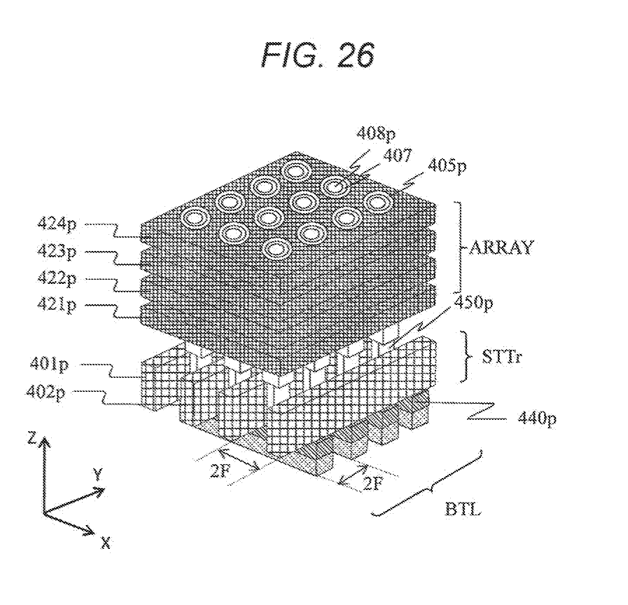

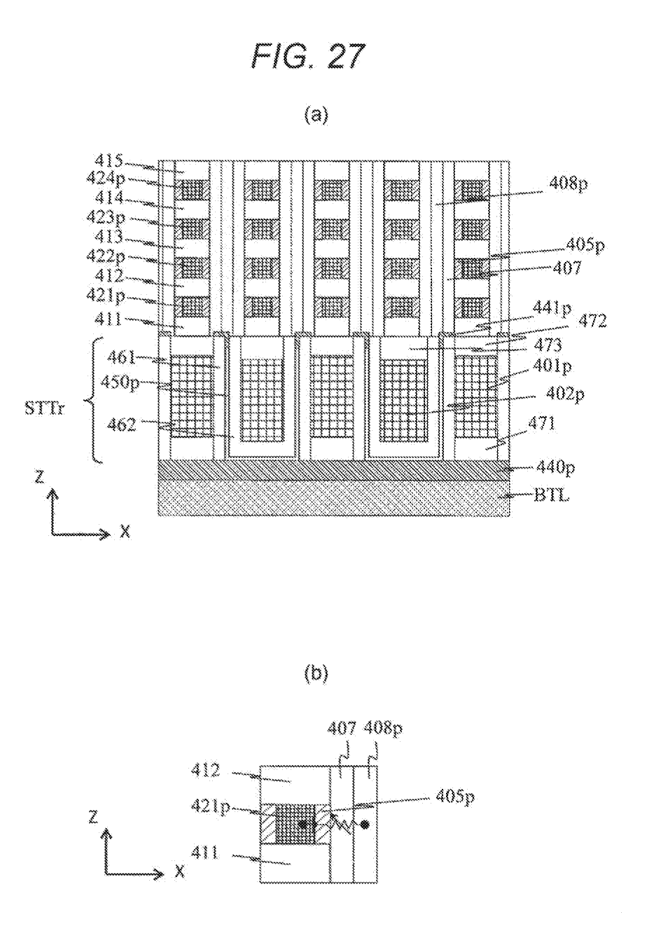

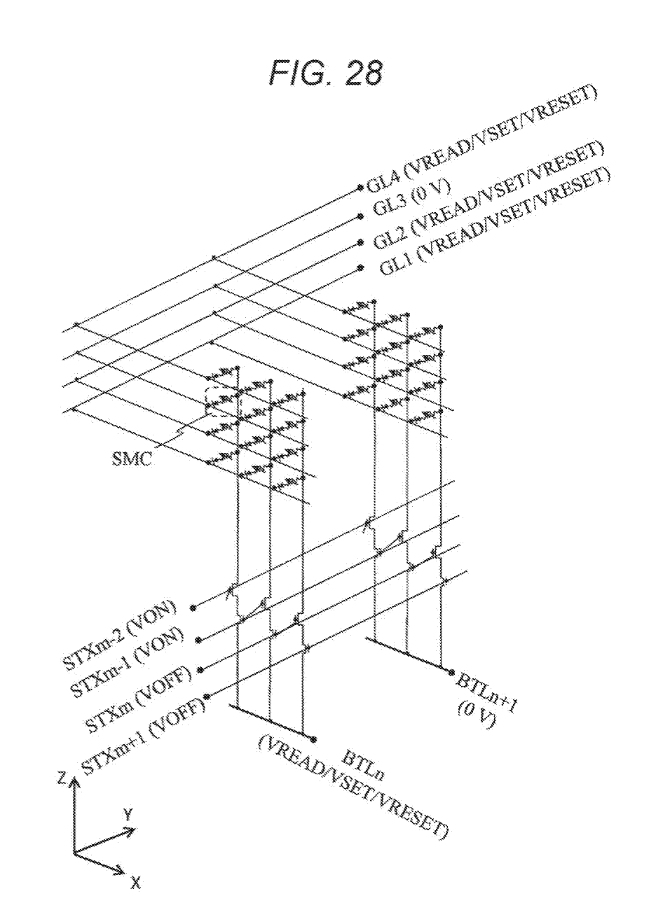

FIG. 26 illustrates a bird's eye view of a device structure of the vertical cross point memory using the selection transistor according to the present invention, FIGS. 27(a) and 27 (b) illustrate cross-sectional views of an XZ plane, and FIG. 28 illustrates an equivalent circuit diagram. A vertical cross point memory array is connected to an electrode via the selection transistor at the lower side. An operation method of the selection transistor is the same as those of the first and second embodiments.

FIG. 26 illustrates lower electrode wiring lines BTL extending in an X direction and formed at a pitch of 2F in a Y direction, selection transistors STTr extending in the Y direction, conductive films 421p, 422p, 423p, and 424p becoming electrodes, memory holes of a Z direction formed in a laminate, resistance change material films 407 in the memory holes, and conductive films 408p. The memory holes are formed at a pitch of 2F in the X direction and the Y direction.

FIG. 27(a) is a cross-sectional view of the XZ plane of FIG. 26. Insulating films 411, 412, 413, 414, and 415 omitted in FIG. 26 are also illustrated. Diodes are formed in sidewalls in the memory holes of the conductive films 421p, 422p, 423p, and 424p. The diodes can be realized by forming the conductive films 421p, 422p, 423p, and 424p using N-type silicon and forming 405p using a P-type semiconductor layer, in FIG. 27(a). FIG. 27(b) illustrates an extraction part of FIG. 27(a). The memory cell including the diode including the N-type silicon layer 421p and a P-type semiconductor layer 405p and the resistance change material film 407 and the electrode 408p extending in a Z direction are illustrated. The memory cell including the diode and the resistance change memory is formed as illustrated in the equivalent circuit diagram of FIG. 27 (b).

As illustrated in FIG. 27(a), STTr is formed using gate electrodes 401p and 402p, insulating films 471, 472, and 473, gate insulating films 461 and 462, and channel semiconductor layers 450p. The channel semiconductor layers 450p are disposed such that the two channel semiconductor layers 450p adjacent to each other in the X direction are connected via a gate insulating film 462 below the gate electrode 402p and the channel semiconductor layers 450p contact an N-type semiconductor layer 440p to be a part of a lower electrode at a connection portion. Similar to the first embodiment, because a width of the X direction of a contact portion of 440p and 450p is larger than the film thickness of 450p, 440p and 450p can be contacted over a wide area. Therefore, contact resistance between 440p and 450p can be reduced. An N-type semiconductor layer 441p is formed on 450p and is connected to the conductive film 408p of the memory cell array.

As illustrated in FIG. 28, in a read operation, the channel semiconductor layer 450p of the lower selection transistor STTr including the selection cell is caused to enter a conductive state. In FIG. 28, an on voltage is applied to STXm−2 and STXm−1 of gates STXm−2, STXm−1, STXm, and STXm+1 of STTr and an off voltage is applied to the remaining gates. As a result, one place of the X direction is selected. VREAD (for example, 1 V) is applied to BTL connected to the selection cell via STTr among a plurality of BTLs formed in the Y direction and 0 V is applied to the other BTLs. For the Z direction, 0 V is applied to the electrode layer including the selection cell and VREAD is applied to the other electrode layers. In the selection cell, because a forward voltage is applied to the diode, a current flows and in the other memory cells, because 0 V is applied to the diode or a backward voltage is applied to the diode, a current does not flow. Therefore, because the current flows through only the selection cell, the current is detected by a read circuit connected to BTL, so that resistance of the selection cell is determined and read can be performed.

Likewise, in a write operation, that is, a set operation and a reset operation, the channel semiconductor layer 450p of the lower selection transistor STTr including the selection cell is caused to enter a conductive state. In FIG. 28, an on voltage is applied to STXm−2 and STXm−1 of the gates STXm−2, STXm−1, STXm, and STXm+1 of STTr and an off voltage is applied to the remaining gates. As a result, one place of the X direction is selected. In the case of the set operation, VSET (for example, 3 V) is applied to BTL connected to the selection cell via STTr among the plurality of BTLs formed in the Y direction and in the case of the reset operation, VRESET (for example, 2 V) is applied to BTL and 0 V is applied to the other BTLs. For the Z direction, 0 V is applied to the electrode layer including the selection cell and in the case of the set operation, VSET (for example, 3 V) is applied to the other electrode layers and in the case of the reset operation, VRESET (for example, 2 V) is applied to the other electrode layers. In the selection cell, because a forward voltage is applied to the diode, a current flows and in the other memory cells, because 0 V is applied to the diode or a backward voltage is applied to the diode, a current does not flow. Therefore, because the current flows through only the selection cell, the set operation and the reset operation can be selectively executed.

In the finished semiconductor storage device, because the memory cells can be formed at the pitch of 2F in both the X direction and the Y direction, a large capacity and reduction of a bit cost are enabled. In addition, the finished semiconductor storage device is applied to an information processing device such as storages and servers, so that the information processing device can realize performance improvement using a storage device having a low cost and a large capacity.

### Fourth Embodiment

In the first embodiment, known manufacturing technology is used when memory cells are formed after laminating insulating films 11, 12, 13, 14, and 15, N-type polysilicon layers 21p, 22p, 23p, and 24p becoming memory cell gates, and an N-type polysilicon layer 25p becoming an upper electrode alternately to form a laminate. However, when the memory cells are formed, protective amorphous silicon layers 201a and 202a can be used, similar to formation of gate insulating films GOX1_Y and GOX2_X and channel silicon layers 50p and 51p of STTGY and STTGX.

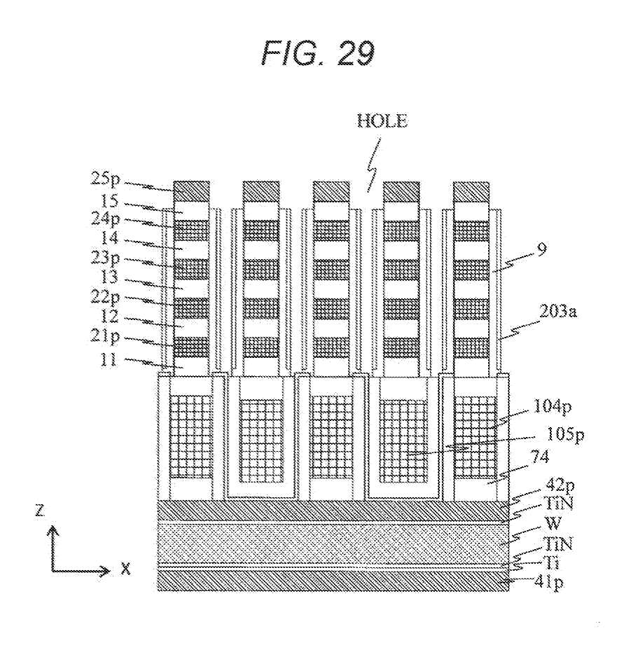

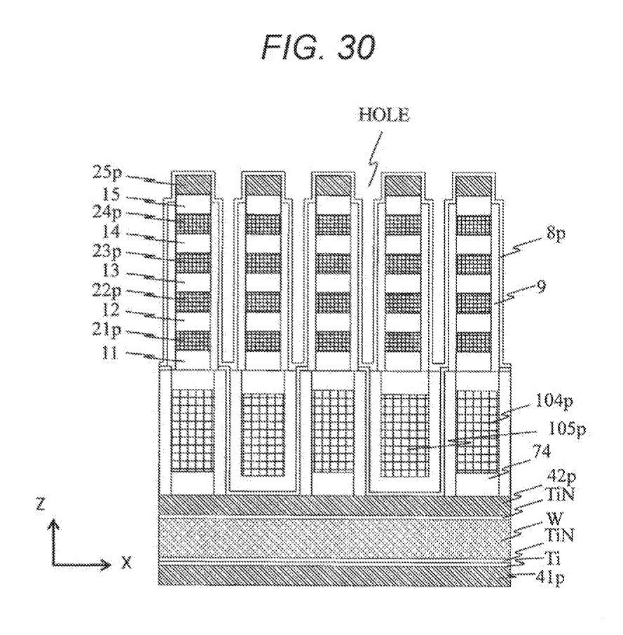

A method of manufacturing a semiconductor storage device according to a fourth embodiment will be described using FIGS. 29 to 31. In FIGS. 29 to 31, the lower side of the laminate is configured using an X selection transistor STTrX according to the first embodiment. This is a configuration of the case in which an N-type polysilicon layer 43p (refer to FIG. 20) is not used on the channel semiconductor layer 51p of the X selection transistor STTrX. However, the invention according to the fourth embodiment does not depend on a configuration of a base. After laminating the insulating films 11, 12, 13, 14, and 15, the N-type polysilicon layers 21p, 22p, 23p, and 24p becoming the memory cell gates, and the N-type polysilicon layer 25p becoming the upper electrode alternately to form the laminate, a hole HOLE reaching a diffusion layer formed on the channel silicon layer 51p is formed in the laminate. Next, after a gate insulating film 9 and a protective amorphous silicon layer 203a are formed, a top surface of the laminate, the gate insulating film 9 of a bottom portion of HOLE, and the protective amorphous silicon layer 203a are removed by etch-back processing (FIG. 29). Next, the protective amorphous silicon layer 203a is removed by wet etching and a channel semiconductor layer 8p is formed (FIG. 30). The channel semiconductor layer 8p can be formed of a silicon layer of a single layer, for example.

When the etch-back processing is executed, the gate insulating film 9 of the sidewall of the laminate is protected by the amorphous silicon layer 203a. Therefore, reliability of the gate insulating film 9 can be secured as compared with the case in which the amorphous silicon layer 203a does not exist.

Next, a phase change material 7 is formed on a surface of the channel silicon layer 8p using a CVD method. After the phase change material 7 is formed not to completely bury HOLE, the remaining hole is covered completely by an insulating film 91. Next, the insulating film 91 and the phase change material 7 are removed to an elevation of the insulating film 15 in HOLE, by the etch-back processing. After an insulating film 92 is formed, the insulating film 92 on the N-typepolysilicon layer 25p is removed by the etch-back processing and is removed to 8p or 8p on a top surface of 25p and the top surface of 25p is exposed. N-type impurities of 25p diffuse into 8p on 25p and 8p includes the N-type impurities of the high concentration.

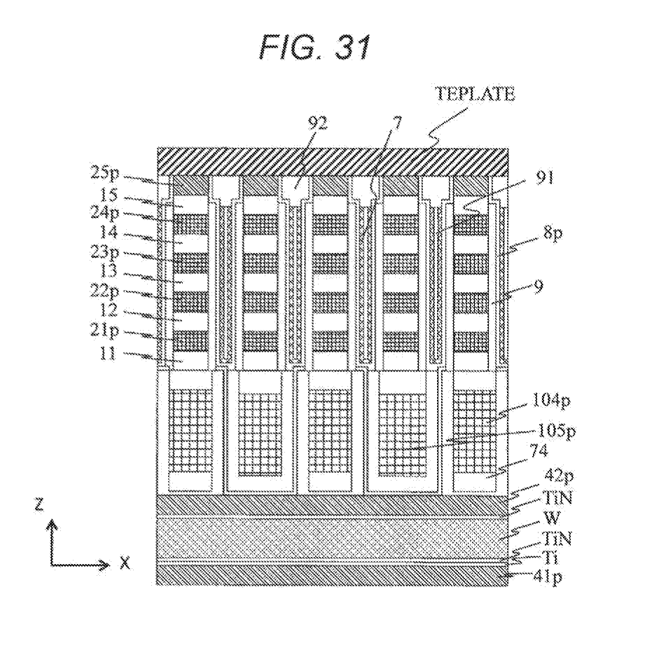

Next, after tungsten/titanium nitride/titanium becoming the upper electrode is formed, the upper electrode is processed (FIG. 31).

Next, gate electrodes GATE1, GATE2, GATE3, and GATE4 of the memory cells are processed using the known technology. After an interlayer insulating film is formed, a contact STTGXC to feed STTGX, STTGXL connected to STTGXC, the gate electrodes GATE1, GATE2, GATE3, and GATE4 of the memory cells, and a contact to a wiring line MLR for read are formed, a wiring line connected to a peripheral circuit is formed, and the semiconductor storage device is finished.

In the finished semiconductor storage device, because reliability of the gate insulating film 9 of the memory cell can be secured, the insulating film 9 can be formed thinly. For this reason, high integration can be realized by reducing a diameter of HOLE. Therefore, a bit cost can be reduced.

### REFERENCE SIGNS LIST

7 phase change material layer
8p, 50p, 51p channel semiconductor layer
9 gate insulating film
11, 12, 13, 14, 15 insulating film
21p, 22p, 23p, 24p gate polysilicon layer
25p, 40p, 41p, 42p N-type semiconductor layer
71, 72, 73, 74, 75, 76 insulating film
81 insulating film
91, 92 insulating film
101p, 102p, 103p, 104p, 105p gate polysilicon layer
201a, 202a, 203a protective amorphous silicon layer
301p, 302p, 303p, 304p gate electrode layer
308p channel semiconductor layer
311, 312, 313, 314, 315 insulating film
321p, 322p, 323p, 324p gate electrode layer
331, 333 silicon oxide film
332 silicon nitride film
340p, 341p, 342p, 343p N-type semiconductor layer
350p, 351p channel semiconductor layer
361, 362, 363, 364 gate insulating film
371, 372, 373, 374, 375, 376 insulating film
401p, 402p gate electrode layer
405p P-type semiconductor layer
407 resistance change material layer
408p conductive film
411, 412, 413, 414, 415 insulating film
421p, 422p, 423p, 424p N-type semiconductor layer
440p, 441p N-type semiconductor layer
450p channel semiconductor layer
461, 462 gate insulating film
471, 472, 473 insulating film
1001 I/O interface
1002 memory cell array
1003, 1004, 1005, 1006 voltage source
1007 voltage selector
1008 wiring line selector
1009 control unit
1010 read unit
1011 management region
GOX1_X, GOX2_X, GOX1_Y, GOX2_Y gate insulating film
ILD interlayer insulating film
BEPLATE plate-like lower electrode
MLR, MLRn−1, MLRn, MLRn+1 wiring line for read operation
MLRC contact to feed MLR
MLRL wiring line to feed MLR
TEPLATE plate-like upper electrode
F minimum processing dimension
ARRAY phase change memory chain array
PCMCHAIN phase change memory chain
SPCMCHAIN selection phase change chain
USPCMCHAIN non-selection phase change chain
STTrX selection transistor to perform selection of X direction
STTrY selection transistor to perform selection of Y direction
STTrX1, STTrX2 selection transistor to perform selection of X direction
STTrY1, STTrY2 selection transistor to perform selection of Y direction
STTGX gate of selection transistor to perform selection of X direction
STTGY gate of selection transistor to perform selection of Y direction
STTGXC contact to STTGX
STTGYC contact to STTGY
STTGXL wiring line for feed to STTGX
STTGYL wiring line for feed to STTGY
STTGXLC contact to STTGX
STTGYLC contact TO STTGY
BELC contact to connect BEPLATE and peripheral circuit
TELC contact to connect TEPLATE and peripheral circuit
GATE1, GATE2, GATE3, GATE4 gate electrode of transistor
GL1, GL2, GL3, GL4 terminal to feed gate
STXm−1, STXm, STXm selection transistor gate
STYn−2, STYn−1, STYn, STYn+1, STYn+2 selection transistor gate
SMC selection memory cell
USMC non-selection memory cell
VREAD read voltage
VSET set voltage
VRESET reset voltage
X, Y, Z direction
VON on voltage of transistor
VOFF off voltage of transistor
VHON half-on voltage of transistor
HOLE memory hole
DSTTr, USTTr selection transistor
DSTm−2, DSTm−1, DSTm, DSTm selection transistor gate
USTm−2, USTm−1, USTm, USTm selection transistor gate
Vthc potential of threshold determination level
Vpass voltage applied to gate of non-selection cell
Vth threshold voltage
STTr selection transistor
BTL electrode wiring line

1. A semiconductor storage device, comprising:
a plate-like lower electrode which is formed on a semiconductor substrate;
an upper electrode which is formed on the lower electrode;
a plurality of memory chains which are disposed between the lower electrode and the upper electrode and are obtained by connecting a plurality of memory cells to be electrically rewritable in series; and
a first selection transistor which is connected to one end of the memory chains,
wherein the plurality of memory chains are arranged in a matrix along a first direction in a semiconductor substrate surface and a second direction orthogonal to the first direction in the semiconductor substrate surface, with a longitudinal direction thereof matched with a normal direction of the semiconductor substrate,
the first selection transistor has a plurality of gates which are formed to be arranged in parallel in the first direction at the same pitch as an arrangement pitch of the memory chains of the first direction and extend in the second direction, a gate insulating film which is formed to contact each facing sidewall between the plurality of gates, and a first channel semiconductor layer which is formed to be interposed by the plurality of gates with the gate insulating film therebetween, and
in the first channel semiconductor layer, both channel semiconductor layers formed with the gate insulating film therebetween in the vicinity of both sides of every other gate among the plurality of gates are connected between the gate and the lower electrode or the upper electrode as a result of a simultaneous film formation process or a part of both channel semiconductor layers remains between the gate and the lower electrode or the upper electrode as the result of the simultaneous film formation process.

2. The semiconductor storage device according to claim 1, wherein the memory cell is a phase change memory.

3. The semiconductor storage device according to claim 2, wherein the gate of the first selection transistor is fed via a contact hole formed from the lower side of the gate of the first selection transistor.

4. The semiconductor storage device according to claim 2, wherein the gate of the first selection transistor is formed using two or more material layers.

5. The semiconductor storage device according to claim 2, further comprising:
a second selection transistor which is connected in series to the first selection transistor between the lower electrode and a memory chain array, in addition to the first selection transistor,
wherein the second selection transistor has a plurality of gates which are formed to be arranged in parallel in the second direction at the same pitch as an arrangement pitch of the memory chains of the second direction and extend in the first direction, a gate insulating film which is formed to contact each facing sidewall between the plurality of gates, and a second channel semiconductor layer which is formed to be interposed by the plurality of gates with the gate insulating film therebetween, and
the second channel semiconductor layer of the second selection transistor faces the gate of the second selection transistor with the gate insulating film therebetween at both sides of the second direction, the gate of the second selection transistor faces the second channel semiconductor layer with the gate insulating film therebetween at both sides of the second direction, and the gate of the second selection transistor has a shape different for every other gate in the second direction.

6. The semiconductor storage device according to claim 5, further comprising:
a metal wiring line that extends in the second direction between the first selection transistor and the second selection transistor and is electrically connected to the first channel semiconductor layer of the first selection transistor and the second channel semiconductor layer of the second selection transistor.

7. The semiconductor storage device according to claim 1, wherein the first channel semiconductor layer of the first selection transistor is formed using a semiconductor layer of a single layer.

8. The semiconductor storage device according to claim 1, wherein a source/drain diffusion layer formed on the first channel semiconductor layer is formed to contact the first channel semiconductor layer, on every other gate in the gates of the first selection transistor.

9. The semiconductor storage device according to claim 1, wherein the memory cell is a flash memory.

10. The semiconductor storage device according to claim 1, wherein the memory cell is a vertical cross point memory.

11. The semiconductor storage device according to claim 1, wherein the thickness of the first direction of the first channel semiconductor layer of the first selection transistor is set to 5 nm or less.

12. The semiconductor storage device according to claim 5, wherein the thickness of the second direction of the second channel semiconductor layer of the second selection transistor is set to 5 nm or less.

13. A method of manufacturing a semiconductor storage device, comprising:
(a) a step of forming a metal film becoming a lower electrode on a semiconductor substrate with an interlayer insulating film therebetween;
(b) a step of forming a first insulating film on the lower electrode;
(c) a step of forming a first gate electrode layer and a second insulating film on the first insulating film;
(d) a step of patterning the second insulating film, the first gate electrode layer, and the first insulating film to be arranged with a predetermined width at a double pitch of an arrangement pitch of a memory chain array of a first direction in a semiconductor substrate surface and extend in a second direction orthogonal to the first direction in the semiconductor substrate surface;
(e) a step of forming a first gate insulating film not to completely bury a space formed by the step (d);
(f) a step of removing the first gate insulating film on a top surface of a pattern formed by the step (d) and the first gate insulating film on the lower electrode in a space formed by the step (d);
(g) a step of forming a first channel semiconductor not to completely bury a space formed by the step (f);
(h) a step of forming a second gate insulating film not to completely bury a space formed by the step (g);
(i) a step of forming a second gate electrode layer; and
(j) a step of separating the second gate electrode layer formed by the step (i) by etch-back processing for each groove formed by the step (d).

14. The method according to claim 13, further comprising:
(b1) a step of forming a contact hole in the first insulating film between the step (b) and the step (c);
(i1) a step of removing the second gate insulating film and the second gate electrode layer, covering the contact hole existing in a space portion formed by the step (d), on the contact hole, between the step (i) and the step (j);
(i2) a step of forming a third gate electrode layer; and
(i3) a step of separating the third gate electrode layer formed by the step (i2) by the etch-back processing for each groove formed by the step (d).

15. The method according to claim 13, further comprising:
(e1) a step of forming a first dummy layer between the step (e) and the step (f); and
(f1) a step of removing the first dummy layer formed by the step (e1) between the step (f) and the step (g).

16. The semiconductor storage device according to claim 6, wherein the thickness of the first direction of the first channel semiconductor layer of the first selection transistor is set to 5 nm or less.
